(19) United States
(12) Patent Application Publication
(10) Pub. No.: US 2020/0091238 A1
(43) Pub. Date: Mar. 19, 2020

(54) STORAGE DEVICE

(71) Applicant: Toshiba Memory Corporation, Tokyo (JP)

(72) Inventor: Tomoya SANUKI, Suzuka Mie (JP)

(21) Appl. No.: 16/285,364

(22) Filed: Feb. 26, 2019

(30) Foreign Application Priority Data
Sep. 14, 2018 (JP) 2018-173092

(51) Int. Cl. H01L 27/24; H01L 45/00

(52) U.S. Cl. CPC H01L 27/2463; H01L 45/1683; H01L 45/1675; H01L 27/2409

(57) ABSTRACT

According to one embodiment, a storage device includes a first conductor extending along a first direction, first variable-resistance elements on the first conductor, and a second conductor on the first variable-resistance elements and extending along a second direction. A plurality of second variable-resistance elements is on the second conductor. A third conductor is on the plurality of second variable-resistance elements. The third conductor extends along the first direction. A first switching element is connected between the second conductor and a corresponding one of the first variable-resistance elements. A second switching element is connected between the third conductor and a corresponding one of second variable-resistance elements.

### CROSS-REFERENCE TO RELATED APPLICATION

This application is based upon and claims the benefit of priority from Japanese Patent Application No. 2018-173092, filed Sep. 14, 2018, the entire contents of which are incorporated herein by reference.

### FIELD

Embodiments described herein relate generally to a storage device.

### BACKGROUND

A storage device that stores data using a switchable resistor of an element is known.

### DESCRIPTION OF THE DRAWINGS

FIG. 1 schematically depicts a storage device according to a first embodiment.

FIG. 2 is a circuit diagram of a memory cell array according to the first embodiment.

FIG. 3 depicts a part of the memory cell array according to the first embodiment.

FIG. 4 depicts another part of the memory cell array according to the first embodiment.

FIGS. 5A and 5B show cross-sectional structures of a part of the memory cell array according to the first embodiment.

FIG. 6 depicts aspects related to explanation of a principle of an operation of a switching element according to the first embodiment.

FIG. 7 shows an example of a variable-resistance element according to the first embodiment.

FIG. 8 shows another example of a variable-resistance element according to the first embodiment.

FIGS. 9A and 9B show aspects of a manufacturing process of a part of the storage device according to the first embodiment.

FIGS. 10A and 10B show aspects of the manufacturing process of a part of the storage device according to the first embodiment.

FIGS. 11A and 11B show aspects of the manufacturing process of a part of the storage device according to the first embodiment.

FIGS. 12A and 12B show aspects of the manufacturing process of a part of the storage device according to the first embodiment.

FIGS. 13A and 13B show aspects of the manufacturing process of a part of the storage device according to the first embodiment.

FIGS. 14A and 14B show aspects of the manufacturing process of a part of the storage device according to the first embodiment.

FIGS. 15A and 15B depict cross-sectional structures of a part of the memory cell array of the storage device of a comparative example.

FIGS. 16A and 16B depict a step of the manufacturing process of a part of the storage device of a comparative example.

FIGS. 17A and 17B depict cross-sectional structures of a part of a memory cell array according to a second embodiment.

FIGS. 18A and 18B depict a step of a manufacturing process of a part of a storage device according to the second embodiment.

FIGS. 19A and 19B depict cross-sectional structures of a part of a memory cell array according to a third embodiment.

FIGS. 20A and 20B depict a step of a manufacturing process of a part of a storage device according to the third embodiment.

FIGS. 21A and 21B show cross-sectional structures of a part of a memory cell array according to a fourth embodiment.

FIGS. 22A and 22B show a step of a manufacturing process of a part of a storage device according to the fourth embodiment.

FIGS. 23A and 23B depict a step that follows FIGS. 22A and 22B in the manufacturing process of a part of the storage device according to the fourth embodiment.

FIGS. 24A and 24B depict a cross-sectional structure of a part of a memory cell array according to a fifth embodiment.

FIGS. 25A and 25B depict a step of a manufacturing process of a part of a storage device according to the fifth embodiment.

FIGS. 26A and 26B depict cross-sectional structures of a part of a memory cell array according to a sixth embodiment.

FIGS. 27A and 27B depict a step of a manufacturing process of a part of a storage device according to the sixth embodiment.

FIG. 28 depicts a planar structure of a part of a memory cell array according to a seventh embodiment.

FIG. 29 depicts a planar structure of another part of the memory cell array according to the seventh embodiment.

FIGS. 30A and 30B depict cross-sectional structures of a part of the memory cell array according to the seventh embodiment.

FIGS. 31A and 31B depict cross-sectional structures of a part of a memory cell array according to an eighth embodiment.

FIGS. 32A and 32B depict cross-sectional structures of a part of a memory cell array according to a ninth embodiment.

FIGS. 33A and 33B depict cross-sectional structures of a part of a memory cell array according to a tenth embodiment.

FIGS. 34A and 34B depict cross-sectional structures of a part of a memory cell array according to an eleventh embodiment.

FIGS. 35A and 35B depict cross-sectional structures of a part of a memory cell array according to a twelfth embodiment.

FIGS. 36A and 36B depict cross-sectional structures of a part of a memory cell array according to a thirteenth embodiment.

FIGS. 37A and 37B depict cross-sectional structures of a part of a memory cell array according to a fourteenth embodiment.

### DETAILED DESCRIPTION

Embodiments provide a high-performance storage device.

In general, according to one embodiment, a storage device, includes a first conductor extending along a first direction, a plurality of first variable-resistance elements on the first conductor, a second conductor on the plurality of first variable-resistance elements, the second conductor extending along a second direction, a plurality of second variable-resistance elements on the second conductor, and a third conductor on the plurality of second variable-resistance elements, the third conductor extending along the first direction. A first switching element is connected between the second conductor and a corresponding one of the first variable-resistance elements.

A second switching element is connected between the third conductor and a corresponding one of second variable-resistance elements.

Hereinafter, example embodiments will be described with reference to the drawings. In the following description, the same reference numerals will be given to those elements having substantially the same function and configuration, and repeated description for each example may be omitted. The drawings are schematic, and the depicted relationships between element thicknesses and/or other dimensions, the ratios between depicted element dimensions may be different from the actual ratio in actual devices. Furthermore, the descriptions of aspects and/or elements of any one embodiment are also applicable as descriptions of any other embodiment as long as such description is not expressly or obviously excluded from said other embodiments.

In the specification and claims, a case where a first element is “connected” to a second element includes a case in which the first element is directly or indirectly connected to the second element via a conductive element interposed therebetween.

### First Embodiment

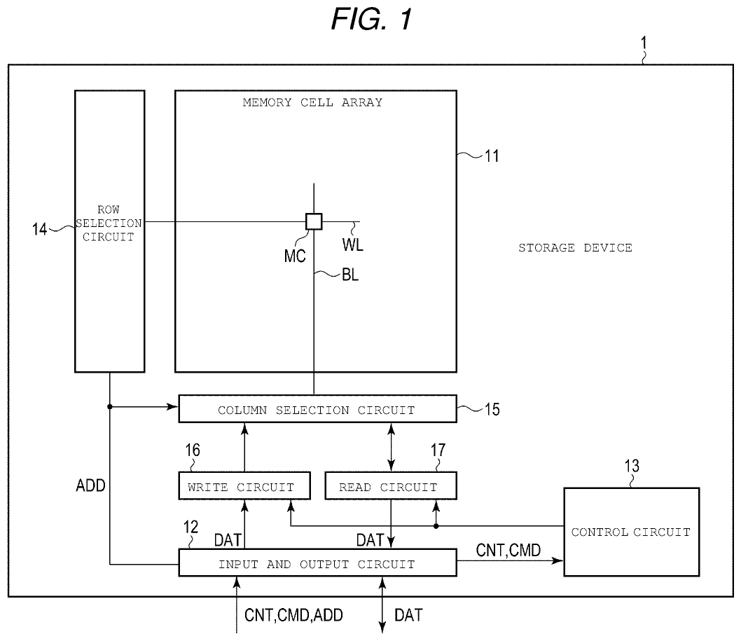

FIG. 1 schematically depicts a storage device according to a first embodiment. As shown in FIG. 1, the storage device 1 includes a memory cell array 11, an input and output circuit 12, a control circuit 13, a row selection circuit 14, a column selection circuit 15, a write circuit 16, and a read circuit 17.

The memory cell array 11 includes a plurality of memory cells MC, a plurality of word lines WL, and a plurality of bit lines BL. The memory cells MC can store data in a nonvolatile manner. Each memory cell MC is connected to one word line WL and one bit line BL. Each word line WL is associated with a row. Each bit line BL is associated with a column. By selecting one row and selecting one or more columns, one or a plurality of memory cells MC are specified/selected.

The input and output circuit 12 receives a plurality of various control signals CNT, various commands CMD, address signals ADD, and data DAT (write data), from a memory controller or the like, and sends data DAT (read data) to the memory controller or the like.

The row selection circuit 14 receives the address signal ADD from the input and output circuit 12 and brings one word line WL that corresponds to the row based on the received address signal ADD into a selected state.

The column selection circuit 15 receives the address signal ADD from the input and output circuit 12 and brings the plurality of bit lines BL that correspond to the column based on the received address signal ADD into a selected state.

The control circuit 13 receives the control signal CNT and the command CMD from the input and output circuit 12. The control circuit 13 controls other elements of the storage device 1, in particular, the write circuit 16 and the read circuit 17, based on the details of the control instructed by the control signal CNT and the details of the command CMD. Specifically, the control circuit 13 controls the write circuit 16 during the writing of data to the memory cell array 11. The control during the data writing includes supply of a voltage used for the data writing to the write circuit 16. Further, the control circuit 13 controls the read circuit 17 during the reading of the data from the memory cell array 11. The control during the data reading includes supply of a voltage used for the data reading to the read circuit 17.

The write circuit 16 receives the write data DAT from the input and output circuit 12 and supplies the voltage used for the data writing to the column selection circuit 15 based on the control of the control circuit 13 and the write data DAT.

The read circuit 17 includes a sense amplifier, and reads the data held in the memory cell MC based on the control of the control circuit 13. The read data is supplied to the input and output circuit 12 as the read data DAT.

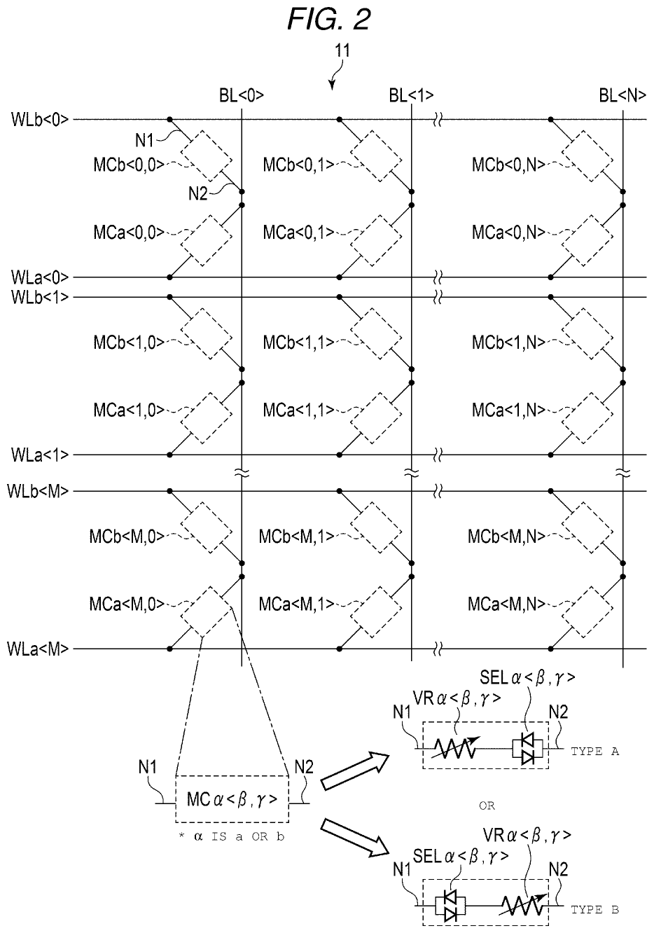

FIG. 2 is a circuit diagram of the memory cell array 11 according to the first embodiment. As shown in FIG. 2, the memory cell array 11 includes M+1 (where M is a natural number) word lines WLa (WLa<0>, WLa<1> . . . and WLa<M>) and M+1 word lines WLb (WLb<0>, WLb<1> . . . and WLb<M>). The memory cell array 11 also includes N+1 (where N is a natural number) number of bit lines BL (BL<0>, BL<1> . . . and BL<N>).

Each memory cell MC has a node N1 and a node N2, is connected to one word line WL at node N1, and is connected to one bit line BL at node N2. More specifically, the memory cell MCa includes a memory cell MCa <β, γ> for all combinations of the cases where β is equal to or greater than 0 and equal to or less than M and all cases where γ is equal to or greater than 0 and equal to or less than N, and the memory cell MCa <β, γ> connects the word line WLa <β> and the bit line BL<γ> to each other. Similarly, the memory cell MCb includes a memory cell MCb <β, γ> for all combinations of the cases where β is equal to or greater than 0 and equal to or less than M and all cases where γ is equal to or greater than 0 and equal to or less than N, and the memory cell MCb <β, γ> connects the word line WLb <β> and the bit line BL<γ> to each other.

Each memory cell MC includes one variable-resistance element VR and one switching element SEL. More specifically, the memory cell MCa <β, γ> includes the variable-resistance element VRa <β, γ> and the switching element SELa <β, γ> for all combinations of the cases where β is equal to or greater than 0 and equal to or less than M and all cases where γ is equal to or greater than 0 and equal to or less than N. The memory cell MCb <β, γ> includes the variable-resistance element <β, γ> and the switching element SELb <β, γ> for all combinations of the cases where β is equal to or greater than 0 and equal to or less than M and all cases where γ is equal to or greater than 0 and equal to or less than N. In each memory cell MC, the variable-resistance element VR and the switching element SEL are connected to each other in series.

In each memory cell MC, the variable-resistance element VR may be connected to the node N1 and the switching element SEL may be connected to the node N2 (type A), or the switching element SEL may be connected to the node N1 and the variable-resistance element VR may be connected to the node N2 (type B). However, it is possible to switch the type corresponding to memory cells MCa and MCb labels in each embodiment.

The variable-resistance element VR can switch between a low resistance state and a high resistance state. The variable-resistance element VR can hold one bit of data by using the two different resistance states.

The switching element SEL has two terminals, and when a voltage less than a first threshold voltage is applied between the two terminals in the first direction, the switching element SEL is in a high resistance state (off state). On the other hand, when a voltage equal to or greater than the first threshold voltage is applied between the two terminals in the first direction, the switching element SEL is in a low resistance state, for example, in an electrically conductive state (on state). The switching element SEL further has the same switching function based on the magnitude of the voltage applied in a second direction opposite to the first direction. By switching on or off the switching element SEL, it is possible to control the supply of the current to the variable-resistance element VR connected to the switching element SEL, that is, the selection or non-selection of the variable-resistance element VR.

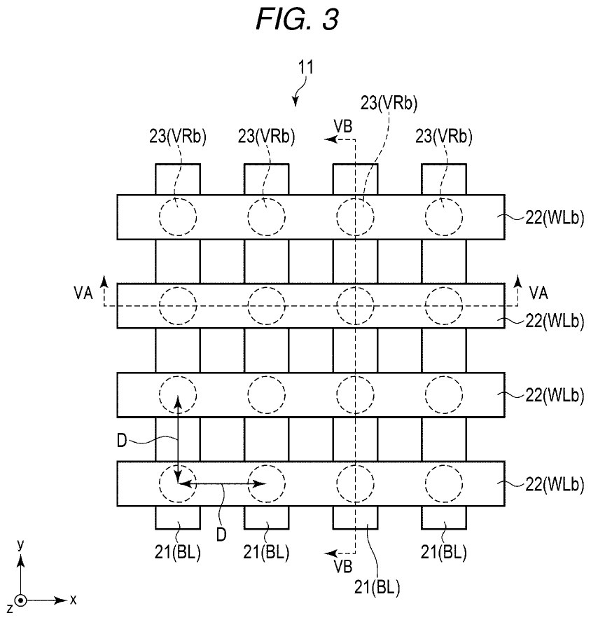

FIG. 3 shows a planar structure of a part of the memory cell array 11 of the first embodiment, that is, a structure along an xy plane. The xy plane is configured with an x axis and a y axis, and the x axis and the y axis are orthogonal to each other.

Furthermore, a z axis is orthogonal to the xy plane.

As shown in FIG. 3, a plurality of conductors 21 are provided. The conductors 21 extend along the y axis and are arranged along the x axis at equal intervals, for example. Each of the conductors 21 function respectively as a bit line BL.

A plurality of conductors 22 are provided above (the z axis direction) of the conductor 21. The conductors 22 extend along the x axis and are arranged along the y axis at equal intervals, for examples. Each of the conductors 22 function respectively as a word line WLb. The spacing intervals between the conductors 22 are equal to the spacing intervals between the conductors 21, for example.

A variable-resistance element 23 is provided between each of the conductors 21 and each of the conductors 22. Each of the variable-resistance elements 23 are connected to only one conductor 21 and only one conductor 22. The variable-resistance elements 23 are arranged in a matrix along the x axis and the y axis. The variable-resistance elements 23 arranged along the x axis are arranged at equal intervals, and the variable-resistance elements 23 arranged along the y axis are arranged at equal intervals. For example, the spacing interval (the distance between the two adjacent centers) of the variable-resistance elements 23 is D. Here, D may be the smallest interval manufacturable based, for example, on limitations in the process of manufacturing the storage device 1.

Each of the variable-resistance elements 23 has a substantially circular shape on the xy plane. The variable-resistance element 23 can function as the variable-resistance element VRb and includes a plurality of layers stacked along the z axis. Each of the plurality of layers is either a conductor, an insulator, or a ferromagnetic body. Further, the details of the variable-resistance element 23 will be described later.

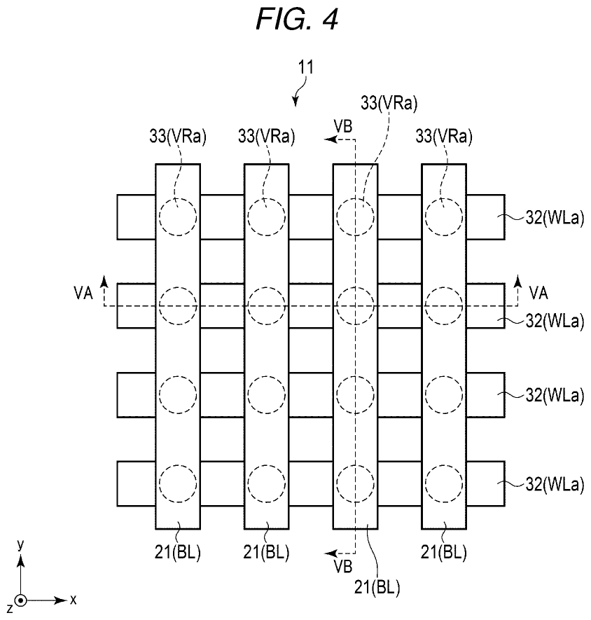

FIG. 4 shows a planar structure of another part of the memory cell array 11 of the first embodiment, and shows a lower structure along the z axis of the structure in FIG. 3.

A plurality of conductors 32 are provided below the z axis of the conductor 21. The conductor 32 extends along the x axis and arranged along the y axis, for example, arranged along the y axis at equal intervals. Each of the conductors 32 functions as one word line WLa. The intervals of the conductors 32 are equal to the intervals of the conductors 21, for example. Each of the conductors 32 has, for example, substantially the same planar shape on the xy plane as that of a conductor 22 and is disposed directly below the z axis of a corresponding conductor 22.

One variable-resistance element 33 is provided between each of the conductors 21 and each of the conductors 32. Each of the variable-resistance elements 33 can be respectively connected electrically to only one conductor 21 and only one conductor 32. Each of the variable-resistance elements 33 has substantially the same shape as that of a variable-resistance element 23, is disposed directly below the z axis of the corresponding variable-resistance element 23, can function as the variable-resistance element VRa, and includes a plurality of layers stacked along the z axis. Each of the plurality of layers is either a conductor, an insulator, or a ferromagnetic body. Further, the details of the variable-resistance element 33 will be described below.

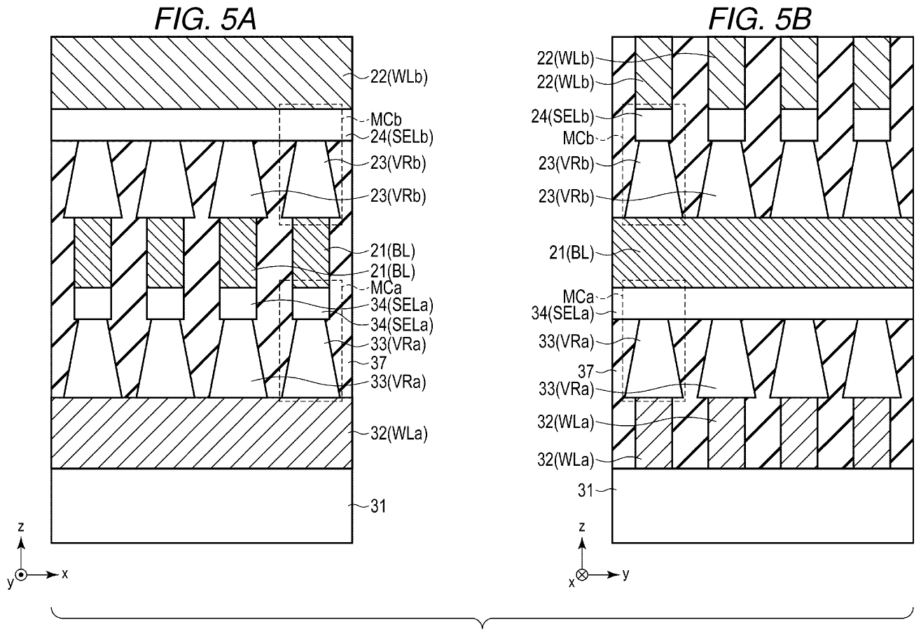

FIGS. 5A and 5B show cross-sectional structures of a part of the memory cell array 11 according to the first embodiment. FIG. 5A shows a structure taken along line VA-VA in FIGS. 3 and 4, and FIG. 5B shows a structure taken along line VB-VB in FIGS. 3 and 4.

As shown in FIGS. 5A and 5B, a plurality of conductors 32 are provided on the upper surface of a semiconductor board 31, such as silicon. A variable-resistance element 33 is provided one layer above the layer on which the conductor 32 is disposed.

A plurality of switching elements 34 are provided on one layer above the layer on which the variable-resistance element 33 is disposed. The switching elements 34 extend along the y axis and are arranged along the x axis. Each of the switching elements 34 is connected to the upper surface of each of the plurality of variable-resistance elements 33 arranged along the y axis, on a bottom surface. The switching element 34 functions as the switching element SELa.

The switching element 34 is, for example, a switching element between the two terminals (e.g., single-pole, single throw switch), the first terminal of the two corresponds to one of the upper surface or the bottom surface of the switching element 34, and the second terminal of the two corresponds to the other one of the upper surface or the bottom surface of the switching element 34. When a voltage less than the first threshold voltage is applied across the switching element 34, the switching element 34 is in a “high resistance” state. When a voltage equal to or greater than the first threshold voltage is applied across the switching element 34, the switching element 34 is in a “low resistance” state. The switching element 34 may operate with any polarity of applied voltage. The switching element 34 may contain at least one type of chalcogen element selected from the group consisting of Te, Se, and S. Otherwise, the switching element 34 may contain a chalcogenide that is a compound containing the chalcogen element. The switching element 34 may further contain at least one type of element selected from the group consisting of B, Al, Ga, In, C, Si, Ge, Sn, As, P, and Sb. In the second embodiment and any of the embodiments thereafter, the switching element 34 may be the switching element between the two terminals as described here.

The switching element 34 may include a further layer, for example, conductor, on one or both of the upper surface and the bottom surface.

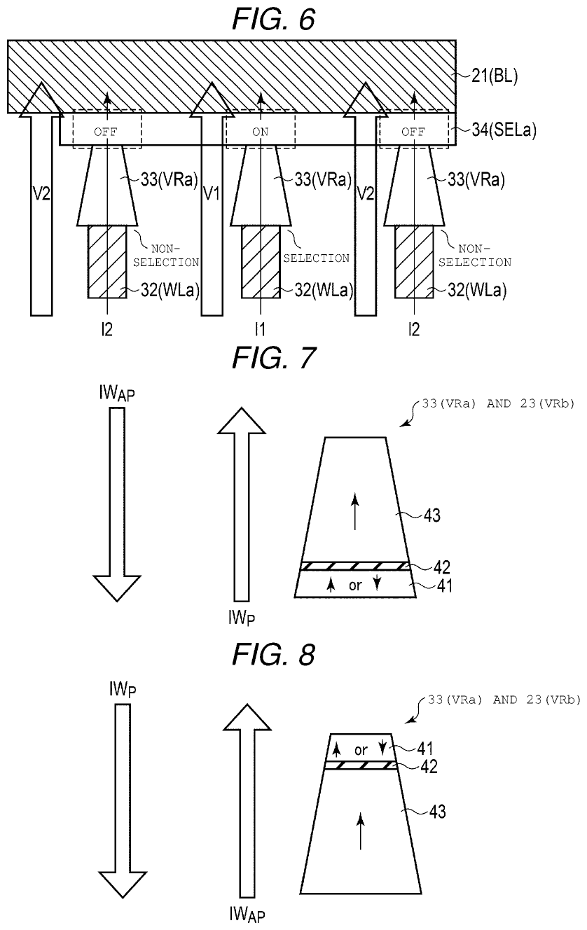

Each of the variable-resistance elements 33 and an upper part of the variable-resistance element 33 of the switching element 34 configure one memory cell MCa. In other words, as shown in FIG. 6, as a voltage is applied to one conductor 32 and one conductor 21 electrically connected to the certain variable-resistance element 33 to be selected, a first voltage V1 is applied only to the upper part of the selected variable-resistance element 33 of the switching element 34. By applying the first voltage V1, a first current I1 flows through the upper part of the variable-resistance element 33 of the switching element 34. On the other hand, only a second voltage V2 lower than the first voltage V1 is applied to the other part of the switching element 34, and accordingly, only a current I2 smaller than the first current I1 flows. The first voltage V1 is selected such that a current having a magnitude equal to or greater than the first threshold voltage flows only to the variable-resistance element 33 being selected, and accordingly, each of the switching elements 34 can be turned on at the upper part of the variable-resistance element 33 being selected. In other words, just one variable-resistance element 33 can be electrically connected to the corresponding one conductor 32 and one conductor 21.

The description returns to FIGS. 5A and 5B. A plurality of conductors 21 are provided on a layer one layer above a layer on which the switching element 34 is disposed. Each of the conductors 21 is disposed on the upper surface of one switching element 34 and has, for example, substantially the same planar shape as the planar shape of one switching element 34.

The plurality of variable-resistance elements 23 are provided on a layer one layer above a layer on which the conductor 21 is disposed. The plurality of variable-resistance elements 23 arranged along the y axis are disposed on the upper surface of one conductor 21.

A plurality of switching elements 24 are provided on a layer one layer above a layer on which the variable-resistance element 23 is disposed. The switching elements 24 extend along the x axis and are arranged along the y axis. Each of the switching elements 24 is connected to the upper surface of each of the plurality of variable-resistance elements 23 arranged along the x axis, on a bottom surface. The switching element 24 functions as the switching element SELb. The switching element 24 is, for example, a switching element between the two terminals, the first terminal of the two corresponds to one of the upper surface or the bottom surface of the switching element 24, and the second terminal of the two corresponds to the other one of the upper surface or the bottom surface of the switching element 24. When a voltage less than a second threshold voltage is applied between the two terminals of the switching element 24, the switching element 24 is in a “high resistance” state. When a voltage equal to or greater than the second threshold voltage is applied between the two terminals of the switching element 24, the switching element 24 is in a “low resistance” state. The switching element 24 may operate with any polarity of voltage. The switching element 24 may contain at least one chalcogen element selected from the group consisting of Te, Se, and S. Otherwise, the switching element 24 may contain a chalcogenide that is a compound containing the chalcogen element. The switching element 24 may further contain at least one type of element selected from the group consisting of B, Al, Ga, In, C, Si, Ge, Sn, As, P, and Sb. In the second embodiment and any of the embodiments thereafter, the switching element 24 may be the switching element between the two terminals as described here.

The switching element 24 may include a further layer, for example, conductor, on one or both of the upper surface and the bottom surface.

Each of the variable-resistance elements 23 and an upper part of the variable-resistance element 23 of the switching element 24 configure one memory cell MCb. In other words, based on the same principle as described for the switching element 34 with reference to FIG. 6, by applying the voltage only to the upper part of the variable-resistance element 23 being selected such that the current having a magnitude equal to or greater than the second threshold voltage flows only to the variable-resistance element 23 being selected, it is possible to turn on each of the switching elements 24 only at the upper part of the variable-resistance element 23 being selected.

A plurality of conductors 22 are provided on a layer one layer above a layer on which the switching element 24 is disposed. Each of the conductors 22 is disposed on the upper surface of one switching element 24 and has, for example, substantially the same planar shape as the planar shape of one switching element 24.

In the region above the board 31, an insulator 37 is provided in a region other than a region where the conductor 32, the variable-resistance element 33, the switching element 34, the conductor 21, the variable-resistance element 23, the switching element 24, and the conductor 22 are disposed.

According to the structure of the memory cell array 11 of the first embodiment, the memory cell MCa is the type A (refer to FIG. 2) and the memory cell MCb is the type B.

FIG. 7 shows an example of the structure of the variable-resistance elements 23 and 33 according to the first embodiment. The variable-resistance elements 23 and 33 contain MTJ elements that contains two ferromagnetic bodies.

The variable-resistance elements 23 and 33 are based on MTJ elements, and the variable-resistance elements 23 and 33 include a ferromagnetic body 41, an insulating non-magnetic body 42, and a ferromagnetic body 43. The ferromagnetic body 41 is disposed at the lowermost part of the variable-resistance element 23, the non-magnetic body 42 is disposed on the upper surface of the ferromagnetic body 41, and the ferromagnetic body 43 is disposed on the upper surface of the non-magnetic body 42. In the ferromagnetic body 41, in a normal operation by the storage device 1, the direction of magnetization is invariable, while the direction of magnetization of the ferromagnetic body 43 is variable. The ferromagnetic bodies 41 and 43 have, for example, easy magnetization axes along the direction passing through interfaces of the ferromagnetic body 41, the non-magnetic body 42, and the ferromagnetic body 43. The ferromagnetic body 41, the non-magnetic body 42, and the ferromagnetic body 43 together show a magnetic resistor effect. Specifically, when the directions of magnetization of the ferromagnetic bodies 41 and 43 are parallel to each other, the variable-resistance elements 23 and 33 exhibit the minimum resistor value. On the other hand, when the directions of magnetization of the ferromagnetic bodies 41 and 43 are parallel to each other, the variable-resistance elements 23 and 33 exhibit the maximum resistor value. States corresponding to the two different resistor values can be assigned to different binary data values, respectively.

When a write current IW_{AP} having a certain magnitude flows from the ferromagnetic body 43 toward the ferromagnetic body 41, the direction of magnetization of the ferromagnetic body 41 becomes antiparallel to the direction of magnetization of the ferromagnetic body 43. On the other hand, when the write current IW_{A}p having a certain magnitude flows from the ferromagnetic body 41 toward the ferromagnetic body 43, the direction of magnetization of the ferromagnetic body 41 becomes parallel to the direction of magnetization of the ferromagnetic body 43.

Each of the variable-resistance elements 23 and 33 may further include the ferromagnetic bodies and (or) additional conductors.

The variable-resistance elements 23 and 33 may have a structure as depicted in FIG. 8. As shown in FIG. 8, the ferromagnetic body 43 is disposed below the ferromagnetic body 41.

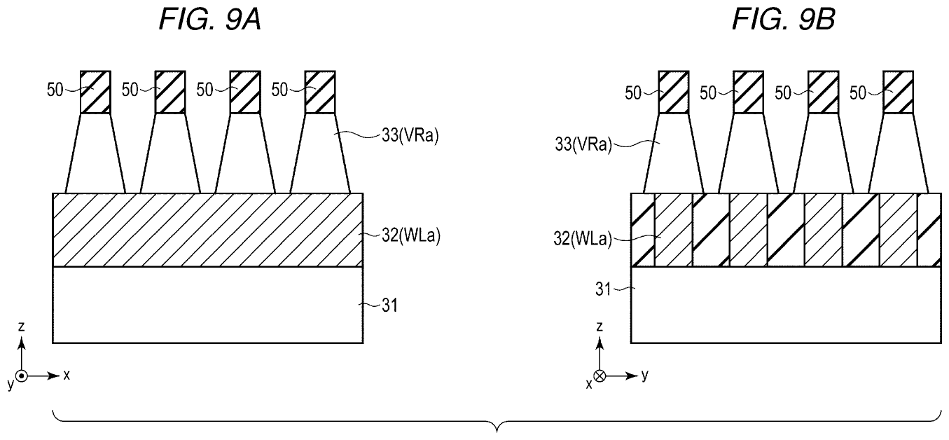

FIGS. 9A to 14B sequentially show steps of a manufacturing process of a part of the storage device 1 of the first embodiment. Each of FIGS. 9A, 10A, 11A, 12A, 13A, and 14A shows sections at the same position as that in FIG. 5A, and each of FIGS. 9B, 10B, 11B, 12B, 13B, and 14B shows sections at the same position as the part in FIG. 5B.

As shown in FIGS. 9A and 9B, a material for conductor 32 is deposited on the board 31. The conductor 32 is patterned by a lithography process, reactive ion etching (RIE) and the like, and accordingly the conductors 32 are formed.

The region between the conductors 32 is filled by a part of the insulator 37. A stacked body for forming the variable-resistance element 33 is deposited on the upper surface of the conductor 32 and the insulator 37 therebetween. The stacked body includes a plurality of layers corresponding to those in the variable-resistance element 33. According to the example of FIG. 7, the stacked body includes, in order from the bottom, a ferromagnetic body, an insulator, and a ferromagnetic body.

A mask material 50 is deposited on the upper surface of the stacked body used to form the variable-resistance element 33. The mask material 50 remains above the region where the variable-resistance element 33 is to be formed, and is open at the other part thereof. The variable-resistance element 33 is formed by etching the stacked body by ion beam etching (IBE) using the mask material 50.

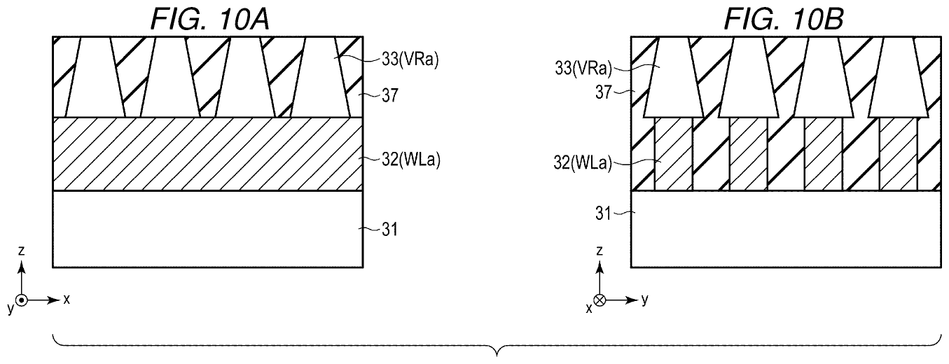

As shown in FIGS. 10A and 10B, the mask material 50 is removed and the region between the variable-resistance elements 33 is filled by a part of the insulator 37.

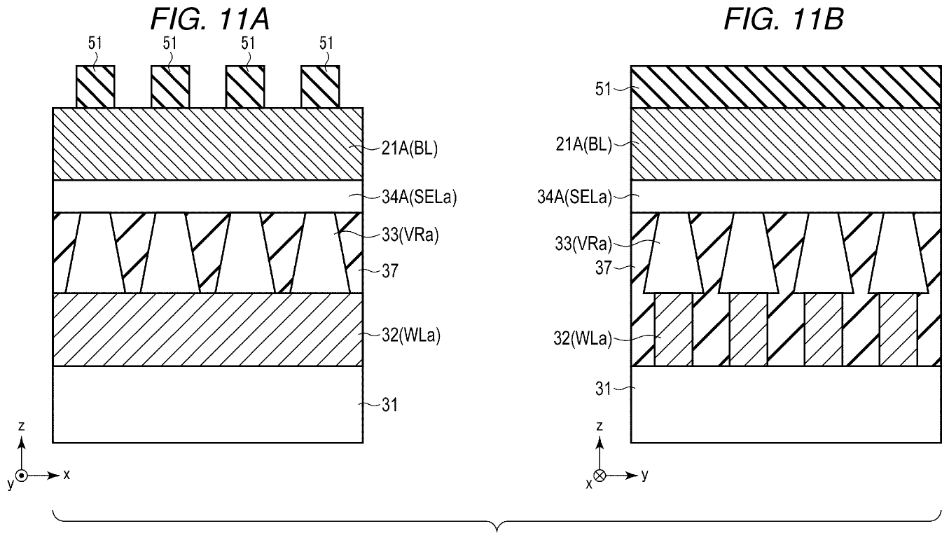

As shown in FIGS. 11A and 11B, a layer 34A is deposited on the upper surface of the variable-resistance element 33 and the insulator 37 therebetween, and a conductor 21A is deposited on the upper surface of the layer 34A. The layer 34A includes the same material as that of the switching element 34 and the conductor 21A contains the same material as that of the conductor 21. A mask material 51 is formed on the upper surface of the conductor 21A. The mask material 51 remains above the region where the switching element 34 and the conductor 21 are to be formed, and are open at the other part thereof.

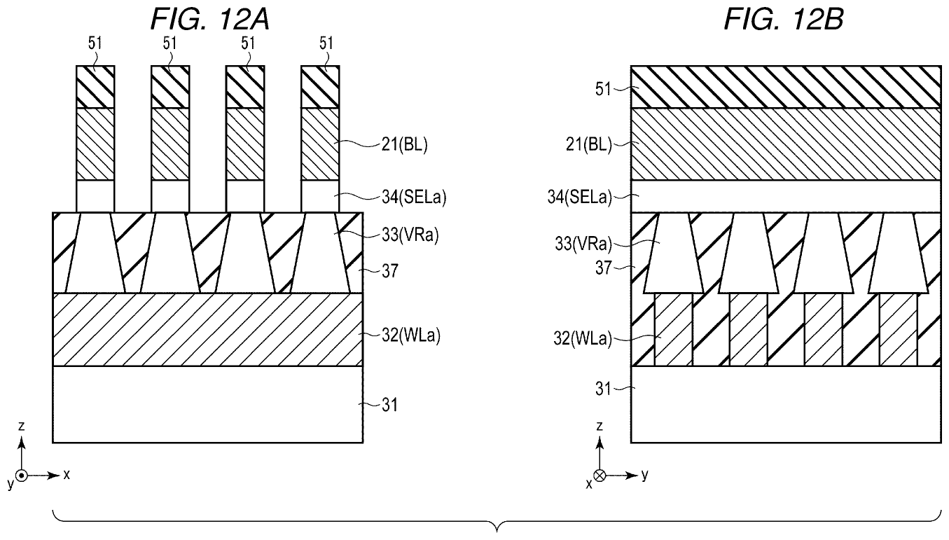

As shown in FIGS. 12A and 12B, parts of the layer 34A and the conductor 21A are removed by etching, such as RIE, through the mask material 51. As a result of etching, the switching element 34 is formed from the layer 34A, and the conductor 21 is formed from the conductor 21A.

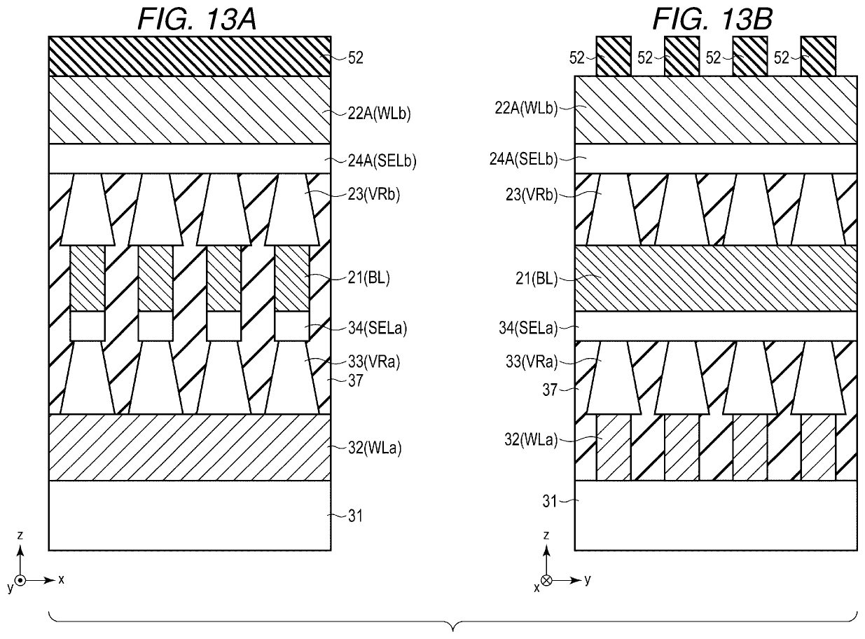

As shown in FIGS. 13A and 13B, the mask material 51 is removed and the region between the stacked bodies of the switching element 34 and the conductor 21 is filled by a part of the insulator 37. A stacked body is deposited on the upper surface of the conductor 21 and the insulator 37 therebetween. The stacked body includes a plurality of layers of the same material as the material of each of the plurality of layers in the variable-resistance element 23 and includes a plurality of layers stacked in the same order as the layers in the variable-resistance element 23. The stacked body includes, in order from the bottom, a ferromagnetic body, an insulator, and a ferromagnetic body. A mask material (not shown) is deposited on the upper surface of the stacked body. The mask material remains above the region where the variable-resistance element 23 is to be formed, and is open at the other part thereof. The variable-resistance element 33 is formed by etching the stacked body 23A by the ion beam etching (IBE) using the mask material.

Next, the region between the variable-resistance elements 23 is fill by a part of the insulator 37. A layer 24A is deposited on the upper surface of the variable-resistance element 23 and the insulator 37 therebetween, and a conductor 22A is deposited on the upper surface of the layer 24A. The layer 24A includes the same material as that of the switching element 24 and the conductor 22A contains the same material as that of the conductor 22. A mask material 52 is formed on the upper surface of the conductor 22A. The mask material 52 remains above the region where the switching element 24 and the conductor 22 are to be formed, and are open at the other part thereof.

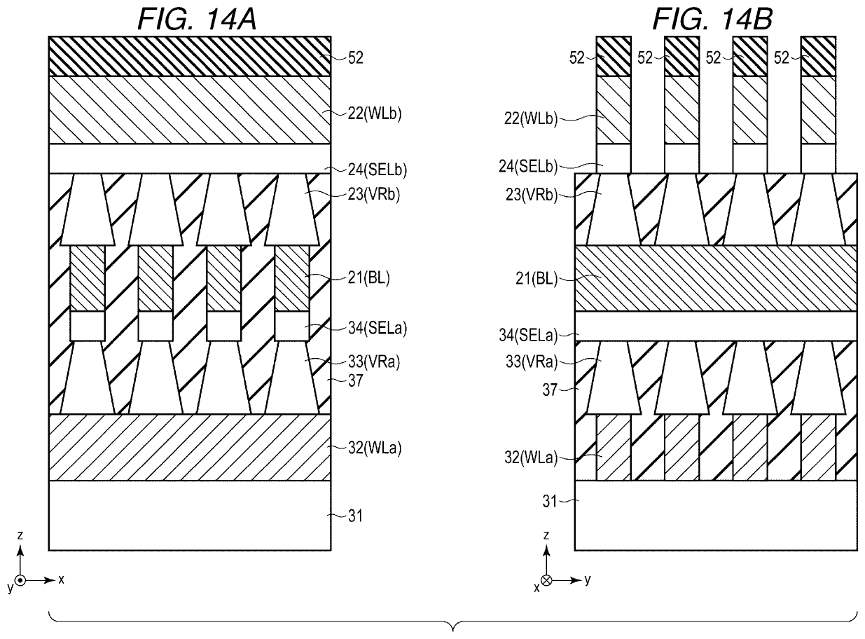

As shown in FIGS. 14A and 14B, the conductor 22A and the layer 24A are successively and partly removed by etching, such as RIE, through the mask material 52. As a result of etching, the switching element 24 is formed from the layer 24A, and the conductor 22 is formed from the conductor 22A.

As shown in FIGS. 5A and 5B, the mask material 52 is removed and the region between the stacked bodies of the switching element 24 and the conductor 22 is filled by a part of the insulator 37. As a result, the structure shown in FIGS. 5A and 5B is obtained.

According to the first embodiment, as described below, it is possible to prevent deterioration of characteristics caused by patterning and to provide a storage device 1 having switching elements 24 and 34 that can be easily patterned.

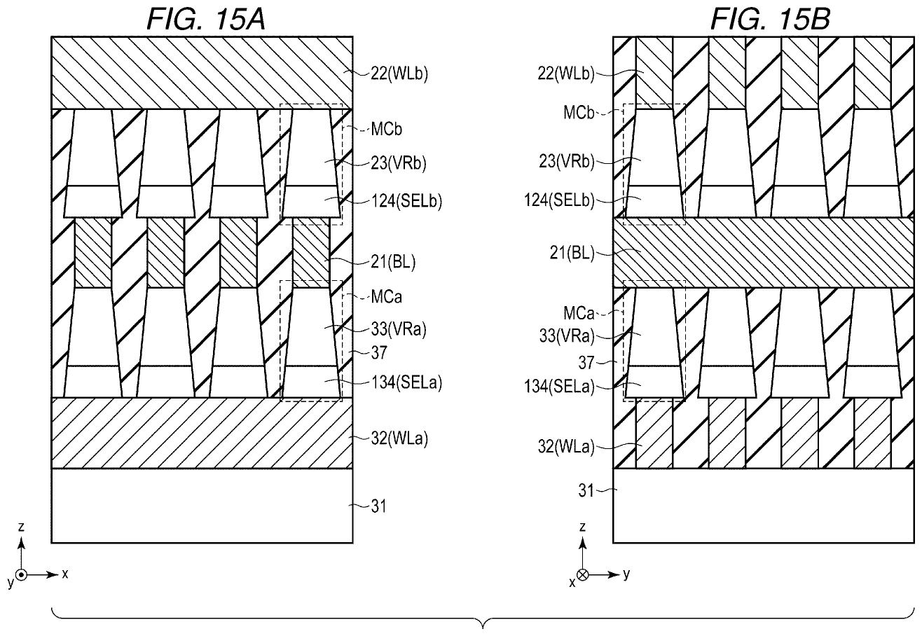

The memory cell array 11 with the circuit shown in FIG. 2 may be formed using the structure in FIGS. 15A and 15B. As shown in FIGS. 15A and 15B, the switching element SELa is formed using switching elements 134, and each of the switching elements 134 is disposed between one conductor 32 and one variable-resistance element 33. The plurality of different variable-resistance elements 33 and the plurality of switching elements 134 connected thereto are independent from each other. Similarly, the switching element SELb is formed using switching elements 124, and each of the switching elements 124 is disposed between one conductor 21 and one variable-resistance element 23. The plurality of switching elements 124 of the different memory cells MC are independent from each other.

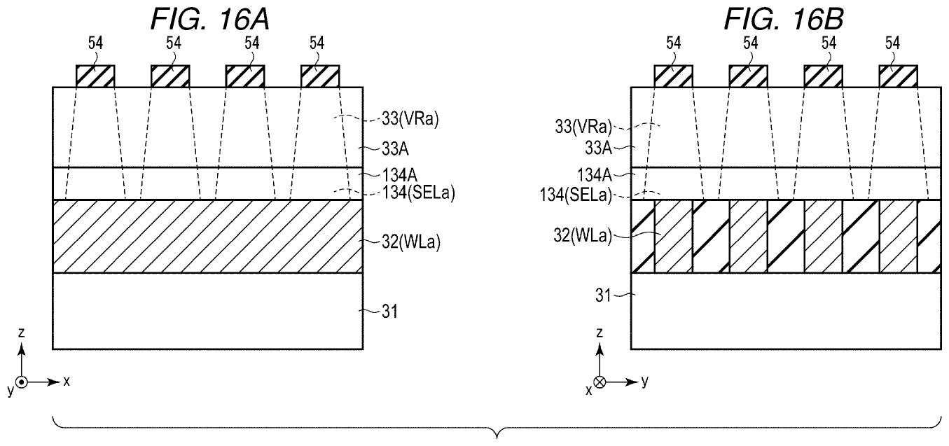

As shown in FIGS. 16A and 16B, the switching element 134 can be formed by etching for patterning the switching element 134 of the layer 134A following the etching through the mask material 54 for patterning the stacked body 33A to the variable-resistance element 33. The patterning of the stacked body 33A is performed by IBE. This is because RIE of the stacked body 33A can deteriorate the magnetic characteristics of the variable-resistance element 33. Since the patterning of the stacked body 33A is performed by IBE, it is assumed that the etching of the subsequent layer 134A is also performed by IBE.

However, the IBE of the layer 134A may deteriorate the characteristics of the switching element 134. Furthermore, the IBE in the step of FIGS. 16A and 16B is required to forma structure with a high aspect ratio. In other words, the interval between the patterns of the mask material 54 is narrow while aiming at a narrow pitch, while the layers 134A and the stacked body 33A to be etched are thick. Formation of the structure with a high aspect ratio is a difficult process for the IBE, and formation of the switching element 134 and the variable-resistance element 33 is difficult. Similarly, the switching element 124 can be formed by the etching following the variable-resistance element 23, and the same tasks as when forming the switching element 134 and the variable-resistance element 33 can occur when forming the switching element 124 and the variable-resistance element 23.

According to the first embodiment, the switching elements 34 extend along the y axis so as to be connected to the plurality of variable-resistance elements 33 arranged along the y axis, and unlike the structure of FIGS. 15A and 15B, the switching elements 34 are not independent for each of the plurality of memory cells MCa arranged along the y axis. Therefore, it is possible to avoid that the formation of the switching element 34 is performed through the IBE aiming at forming the structure with a high aspect ratio, and the switching element 34 can be formed more easily than the structure in FIGS. 15A and 15B. Further, the switching element 34 is disposed between the layer on which the conductor 21 is disposed and the layer on which the variable-resistance element 33 is disposed, and is disposed, for example, on a layer one layer below a layer on which the conductor 21 is disposed. Therefore, the formation can be performed by patterning following the patterning of the conductor 21. Accordingly, since the patterning of the conductor 21 is not required to be performed by IBE, the patterning of the switching element 34 is not required to be performed by IBE, either. Therefore, deterioration of the characteristics of the switching element 34 can be prevented, which would otherwise occur when the switching element 34 is patterned by IBE.

On the other hand, similar to the structure in FIGS. 15A and 15B, the switching element 34 can operate so as to select one memory cell MCa even when the switching element 34 is not independent for each memory cell MCa. Accordingly, while the circuit in FIG. 3 is formed, the switching element 34 can be easily formed and deterioration of the characteristics of the switching element 34 can be prevented as described above.

Similarly, the switching elements 24 extend along the x axis so as to be connected to the plurality of variable-resistance elements 23 arranged along the x axis, and unlike the structure in FIGS. 15A and 15B, the switching elements 24 are not independent for each of the plurality of memory cells MCb arranged along the x axis. Therefore, for the same reason as the formation of the switching element 34, the switching element 24 can be formed more easily than the structure in FIGS. 15A and 15B. Further, the switching element 24 is disposed between the layer on which the conductor 22 is disposed and the layer on which the variable-resistance element 23 is disposed, and is disposed, for example, on a layer one layer below a layer on which the conductor 22 is disposed. Therefore, the formation can be performed by patterning following the patterning of the conductor 22. Accordingly, since the patterning of the conductor 22 is not required to be performed by IBE, the patterning of the switching element 24 is not required to be performed by IBE, either. Therefore, deterioration of the characteristics of the switching element 24 that can occur when the switching element 24 is patterned by IBE can be suppressed. Accordingly, similar to the switching element 34, while the circuit in FIG. 3 is formed, the switching element 24 can be easily formed and deterioration of the characteristics of the switching element 24 can be prevented.

### Second Embodiment

A second embodiment is different from the first embodiment in the structure of the memory cell array 11. More specifically, the second embodiment is different from the first embodiment in the position and shape on the z axis of the switching element 24. Hereinafter, points different from those of the first embodiment will be mainly described.

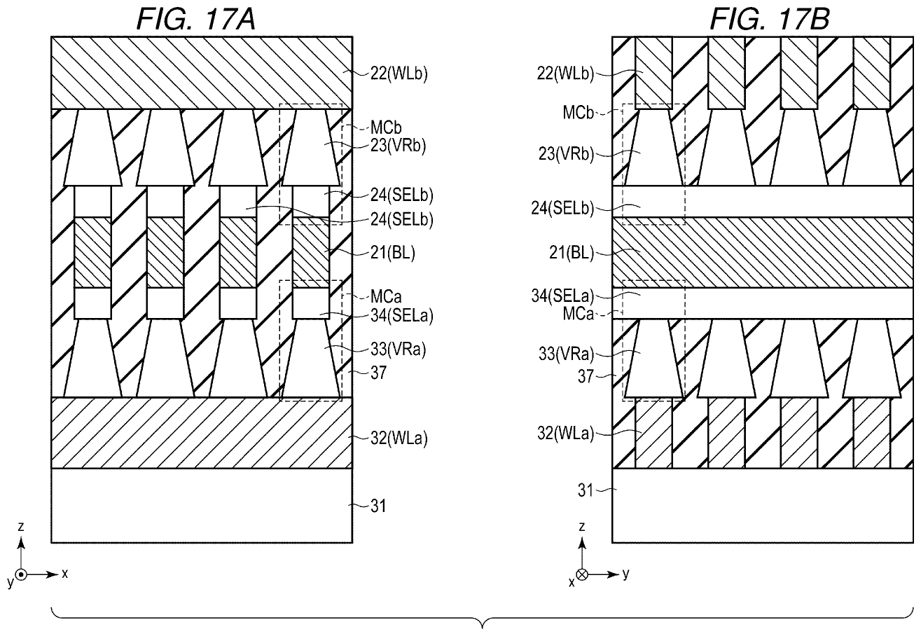

FIGS. 17A and 17B show cross-sectional structures of a part of the memory cell array 11 according to the second embodiment. FIG. 17A shows a structure taken along line VA-VA in FIGS. 3 and 4, and FIG. 17B shows a structure taken along line VB-VB in FIGS. 3 and 4.

As shown in FIGS. 17A and 17B, in a direction of being separated from the board 31, a layer of the conductor 32, a layer of the variable-resistance element 33, a layer of the switching element 34, a layer of the conductor 21, a layer of the switching element 24, a layer of the variable-resistance element 23, and a layer of the conductor 22 are arranged in this order.

The switching elements 24 extend along the y axis and are arranged along the x axis. Each of the switching elements 24 is disposed on the upper surface of one conductor 21. Each of the bottom surfaces of the plurality of variable-resistance elements 23 arranged along the y axis are connected to the upper surface of one switching element 24.

According to the structure of the memory cell array 11 of the second embodiment, both the memory cells MCa and MCb are the type A (refer to FIG. 2).

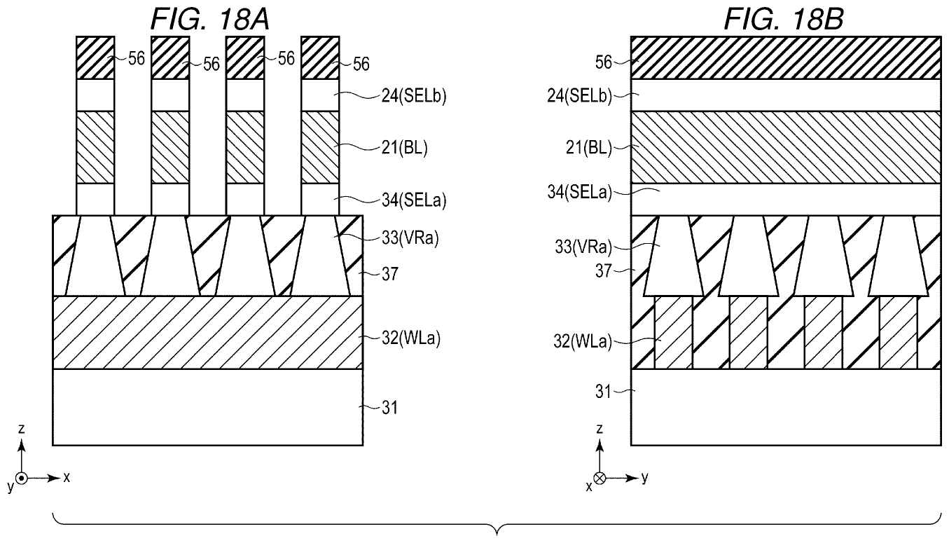

FIGS. 18A and 18B show a step of the manufacturing process of apart of the storage device 1 according to the second embodiment. The step of FIGS. 18A and 18B follows the step of FIGS. 9A and 9B of the first embodiment. As shown in FIGS. 18A and 18B, after the mask material 50 is removed, the layer for forming switching element 34 is deposited on the upper surface of the variable-resistance element 33 and the insulator 37 therebetween, the material for conductor 21 is deposited on the upper surface of the layer for the switching element 34, and the layer for forming the switching element 24 (not shown) is deposited on the upper surface of the material of the conductor 21.

A mask material 56 is formed on the upper surface of the conductor 24A. The mask material 56 remains above the region where the stacked body of the switching element 34, the conductor 21, and the switching element 24 are to be formed. The material layers for switching element 345, the conductor 21, the conductor 22, and the switching element 24 are partly removed by etching, such as RIE, through the mask material 56. As a result of etching, the switching element 34 is formed, the conductor 21 is formed, and the switching element 24 is formed.

As shown in FIGS. 17A and 17B, the mask material 56 is removed and the region between the stacked bodies of the switching element 34, the conductor 21, and the switching element 24 is filled by a part of the insulator 37. A variable-resistance element 23 is formed on the upper surface of each of the switching elements 24 by the same process as the formation of the variable-resistance element 33. The region between the variable-resistance elements 23 is filled by a part of the insulator 37. By a step similar to the steps of FIGS. 13 and 14, the conductor 22 is formed on the upper surface of each of the variable-resistance elements 23. The region between the conductors 22 is filled by a part of the insulator 37. As a result, the structure shown in FIGS. 17A and 17B is obtained.

According to the second embodiment, similar to the first embodiment, the switching elements 34 extend along the y axis and are disposed between the layer on which the conductor 21 is disposed and the layer on which the variable-resistance element 33 is disposed. Accordingly, similar to the first embodiment, deterioration of the characteristics of the switching element 34 can be prevented, which would otherwise occur when the switching element 34 is patterned by IBE.

Further, according to the second embodiment, the switching elements 24 extend along the y axis so as to be connected to the plurality of variable-resistance elements 23 arranged along the y axis, and unlike the structure in FIGS. 15A and 15B, the switching elements 24 are not independent for each of the plurality of memory cells MCb arranged along the y axis. Further, the switching elements 24 are disposed between the layer on which the variable-resistance element 23 is disposed and the layer on which the conductor 21 is disposed, and accordingly, the formation can be performed by patterning following the patterning of the conductor 21. Accordingly, similar to the first embodiment, deterioration of the characteristics of the switching element 24 can be prevented, which would otherwise occur when the switching element 24 is patterned by IBE. Therefore, while the circuit in FIG. 3 is formed, the switching elements 24 and 34 can be easily formed and deterioration of the characteristics of the switching elements 24 and 34 can be prevented.

### Third Embodiment

A third embodiment is different from the first embodiment in the structure of the memory cell array 11. More specifically, the third embodiment is different from the first embodiment in the position and shape on the z axis of the switching element 34. Hereinafter, points different from those of the first embodiment will be mainly described.

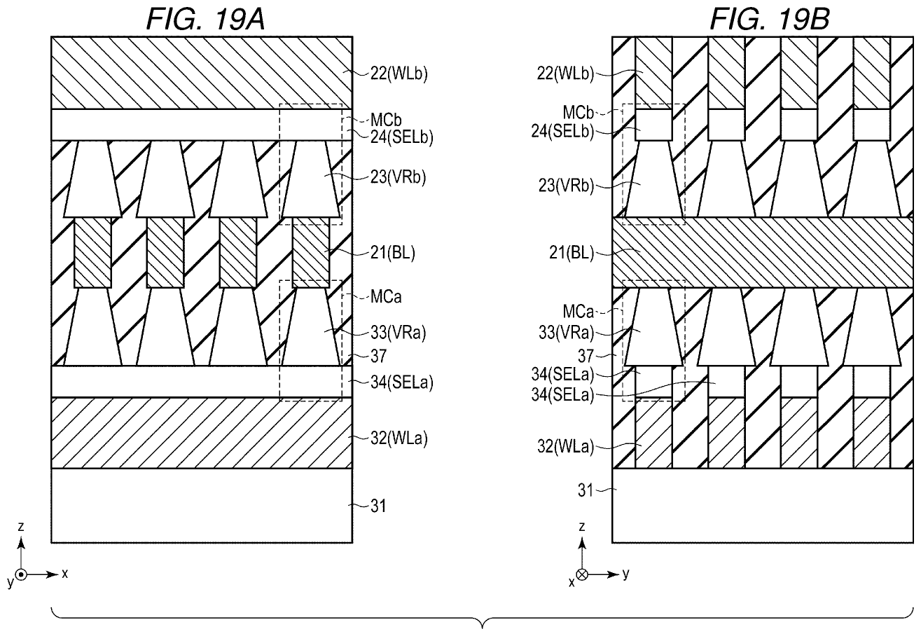

FIGS. 19A and 19B show cross-sectional structures of a part of the memory cell array 11 according to the third embodiment. FIG. 19A shows a structure taken along line VA-VA in FIGS. 3 and 4, and FIG. 19B shows a structure taken along line VB-VB in FIGS. 3 and 4.

As shown in FIGS. 19A and 19B, in a direction of being separated from the board 31, a layer of the conductor 32, a layer of the switching element 34, a layer of the variable-resistance element 33, a layer of the conductor 21, a layer of the variable-resistance element 23, a layer of the switching element 24, and a layer of the conductor 22 are arranged in this order.

The switching elements 34 extend along the x axis and are arranged along the y axis. Each of the switching elements 34 is disposed on the upper surface of one conductor 32. Each of the bottom surfaces of the plurality of variable-resistance elements 33 arranged along the x axis are connected to the upper surface of one switching element 34.

According to the structure of the memory cell array 11 of the third embodiment, both the memory cells MCa and MCb are the type B (refer to FIG. 2).

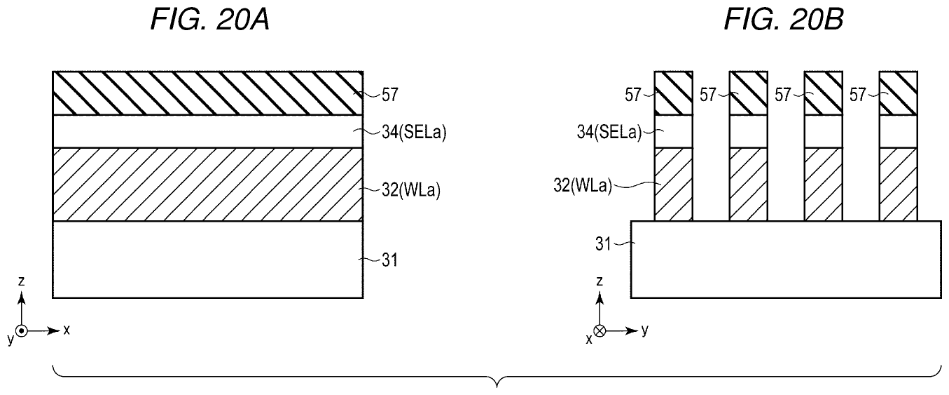

FIGS. 20A and 20B show a step of the manufacturing process of a part of the storage device 1 according to the third embodiment. As shown in FIG. 20, the material for conductor 32 and the layer for the switching element 34 are deposited on the board 31. The mask material 57 is formed on the upper surface of the layer of the switching element 34. The mask material 57 remains above the region where the conductor 32 and the switching element 34 are to be formed by etching, such as RIE.

Next, the mask material 57 is removed and the region between the stacked bodies of the conductor 32 and the switching element 34 is filled by a part of the insulator 37.

Next, as shown in FIGS. 19A and 19B, by the same steps as described with reference to FIGS. 9A and 9B, the variable-resistance elements 33 are formed on the upper surfaces of each of the switching elements 34. Next, the region between the variable-resistance elements 33 is filled by a part of the insulator 37. The subsequent steps are the same as those described with reference to FIGS. 11 to 14. As a result of steps similar to FIGS. 11 to 14, the structure in FIGS. 19A and 19B is obtained.

According to the third embodiment, similar to the first embodiment, the switching elements 24 extend along the x axis and are disposed between the layer on which the conductor 22 is disposed and the layer on which the variable-resistance element 23 is disposed. Accordingly, similar to the first embodiment, deterioration of the characteristics of the switching element 24 can be prevented, which would otherwise occur when the switching element 24 is patterned by IBE.

Further, according to the third embodiment, the switching elements 34 extend along the x axis so as to be connected to the plurality of variable-resistance elements 33 arranged along the x axis, and unlike the structure in FIGS. 15A and 15B, the switching elements 34 are not independent for each of the plurality of memory cells MCa arranged along the x axis. Further, the switching element 34 is disposed between the layer on which the variable-resistance element 33 is disposed and the layer on which the conductor 32 is disposed. Accordingly, the formation can be performed by patterning following the patterning of the conductor 32. Accordingly, similar to the first embodiment, deterioration of the characteristics of the switching element 34 can be prevented, which would otherwise occur when the switching element 34 is patterned by IBE. Therefore, while the circuit in FIG. 3 is formed, the switching elements 24 and 34 can be easily formed and deterioration of the characteristics of the switching elements 24 and 34 can be prevented.

### Fourth Embodiment

A fourth embodiment is different from the first embodiment in the structure of the memory cell array 11. More specifically, the fourth embodiment is different from the first embodiment in the shape of the switching element 24. Hereinafter, points different from those of the first embodiment will be mainly described.

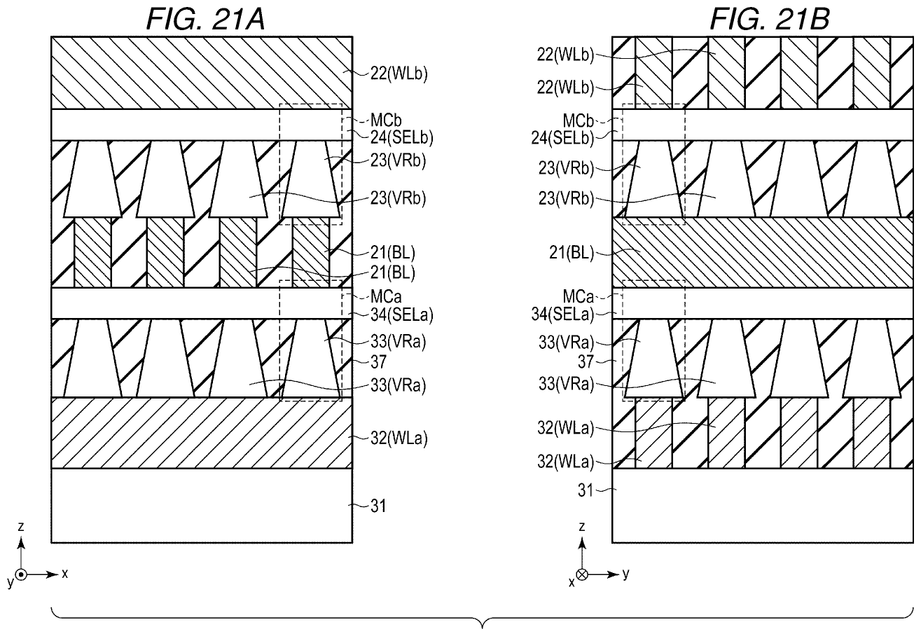

FIGS. 21A and 21B show cross-sectional structures of a part of the memory cell array 11 according to the fourth embodiment. FIG. 21A shows a structure taken along line VA-VA in FIGS. 3 and 4, and FIG. 21B shows a structure taken along line VB-VB in FIGS. 3 and 4.

As shown in FIGS. 21A and 21B, similar to FIGS. 5A and 5B of the first embodiment, in a direction of being separated from the board 31, a layer of the conductor 32, a layer of the variable-resistance element 33, a layer of the switching element 34, a layer of the conductor 21, a layer of the variable-resistance element 23, a layer of the switching element 24, and a layer of the conductor 22 are arranged in this order.

The switching elements 34 spread along the xy plane, spread exceeding a region of at least a set of two or more variable-resistance elements 33 arranged along the x axis and two or more variable-resistance elements 33 arranged along the y axis, and are connected to each of the upper surfaces of the plurality of variable-resistance elements 33 arranged along the xy plane. Similarly, the switching elements 24 spread along the xy plane, spread exceeding a region of at least a set of two or more variable-resistance elements 23 arranged along the x axis and two or more variable-resistance elements 23 arranged along the y axis, and are connected to each of the upper surfaces of the plurality of variable-resistance elements 23 arranged along the xy plane.

According to the structure of the memory cell array 11 of the fourth embodiment, the memory cell MCa is the type A (refer to FIG. 2) and the memory cell MCb is the type B.

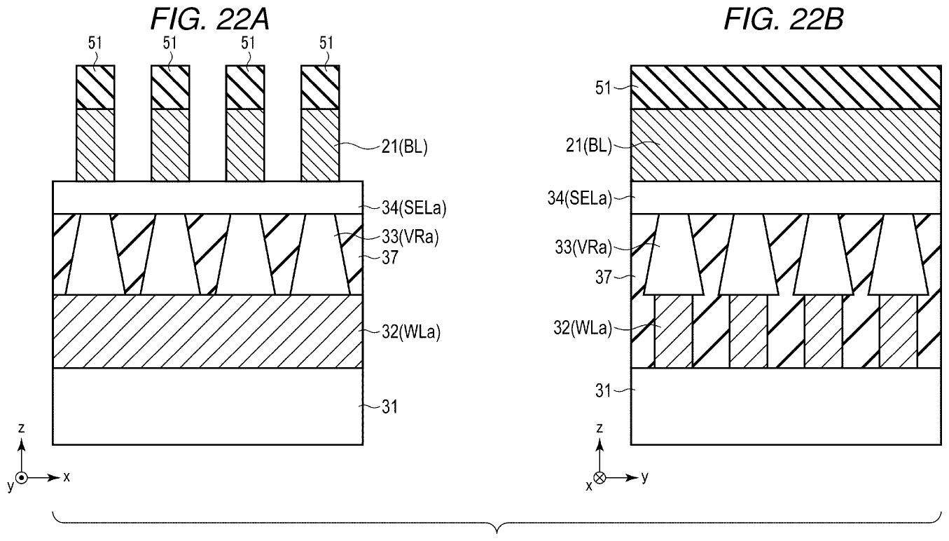

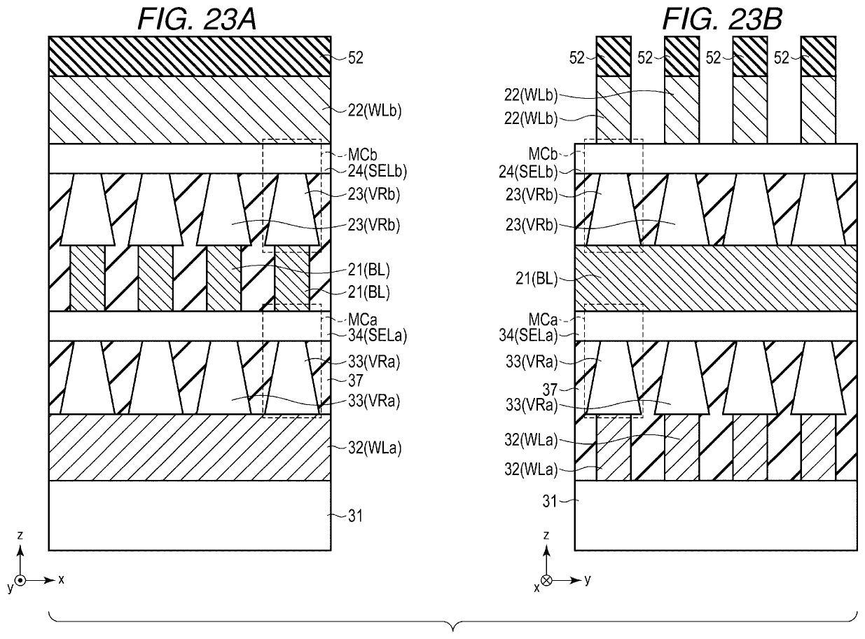

FIGS. 22 and 23 show a step of the manufacturing process of a part of the storage device 1 according to the fourth embodiment. The step of FIGS. 22A and 22B follows the step in the middle of FIGS. 11A and 11B of the first embodiment. As shown in FIGS. 22A and 22B, the etching through the mask material 51 is stopped when the conductor 21 is patterned.

As shown in FIGS. 23A and 23B, the mask material 51 is removed and the region between the conductors 21 is filled by a part of the insulator 37. The layer 24A is deposited on the upper surface of the conductor 21 and the insulator 37 therebetween, the conductor 22A is deposited on the upper surface of the layer 24A, and the mask material 52 is formed on the upper surface of the conductor 22A. By etching, such as RIE, through the mask material 52, the conductor 22A is partly removed, and the conductor 22 is formed from the conductor 22A. Similar to FIGS. 22A and 22B, the etching is stopped when the conductor 22 is patterned. After this, the mask material 52 is removed and the region between the conductors 22 is filled by a part of the insulator 37. As a result, the structure shown in FIGS. 21A and 21B is obtained.

According to the fourth embodiment, the switching elements 24 spread along the xy plane and are connected to the upper surfaces of each of the plurality of variable-resistance elements 23 arranged along the xy plane, and the switching elements 34 spread along the xy plane and are connected to the upper surfaces of each of the plurality of variable-resistance elements 33 arranged along the xy plane. In other words, the switching elements 24 and 34 do not go through the process of separating the switching elements 24 and 34 from each other, and accordingly, it is possible to prevent deterioration of the characteristics of the switching elements 24 and 34, which can occur when performing the patterning by the etching (for example, IBE) for the separation.

On the other hand, as described with reference to FIG. 6, the switching elements 24 and 34 can operate so as to select one memory cell MC even when the switching element 34 is not independent for each memory cell MC similarly to the structure in FIGS. 15A and 15B. Accordingly, while the circuit in FIG. 3 is formed, the switching elements 24 and 34 can be easily formed and deterioration of the characteristics of the switching elements 24 and 34 can be prevented as described above.

### Fifth Embodiment

A fifth embodiment is different from the first embodiment in the structure of the memory cell array 11. More specifically, the fifth embodiment is different from the first embodiment in the shape of the switching element 34 and the position and shape on the z axis of the switching element 24. Hereinafter, points different from those of the first embodiment will be mainly described.

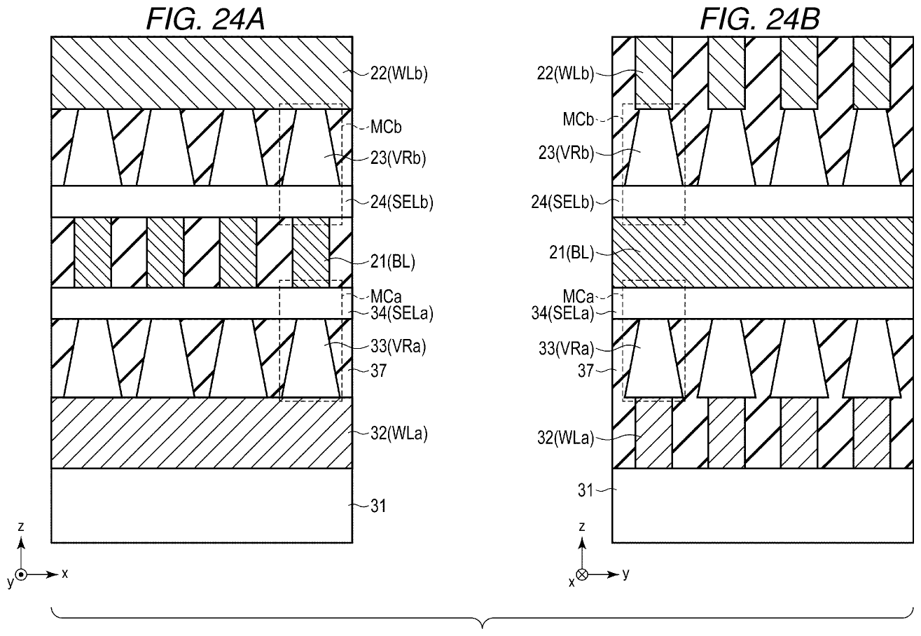

FIGS. 24A and 24B show cross-sectional structures of a part of the memory cell array 11 according to the fifth embodiment. FIG. 24A shows a structure taken along line VA-VA in FIGS. 3 and 4, and FIG. 24B shows a structure taken along line VB-VB in FIGS. 3 and 4.

As shown in FIGS. 24A and 24B, similar to FIGS. 17A and 17B of the second embodiment, in a direction of being separated from the board 31, a layer of the conductor 32, a layer of the variable-resistance element 33, a layer of the switching element 34, a layer of the conductor 21, a layer of the switching element 24, a layer of the variable-resistance element 23, and a layer of the conductor 22 are arranged in this order.

Similar to the fourth embodiment, the switching elements 34 spread along the xy plane and are connected to the upper surfaces of each of the plurality of variable-resistance elements 33 arranged along the xy plane. Further, similar to the fourth embodiment, the switching elements 24 spread along the xy plane and are connected to the bottom surfaces of each of the plurality of variable-resistance elements 23 arranged along the xy plane.

According to the structure of the memory cell array 11 of the fifth embodiment, both the memory cells MCa and MCb are the type A (refer to FIG. 2).

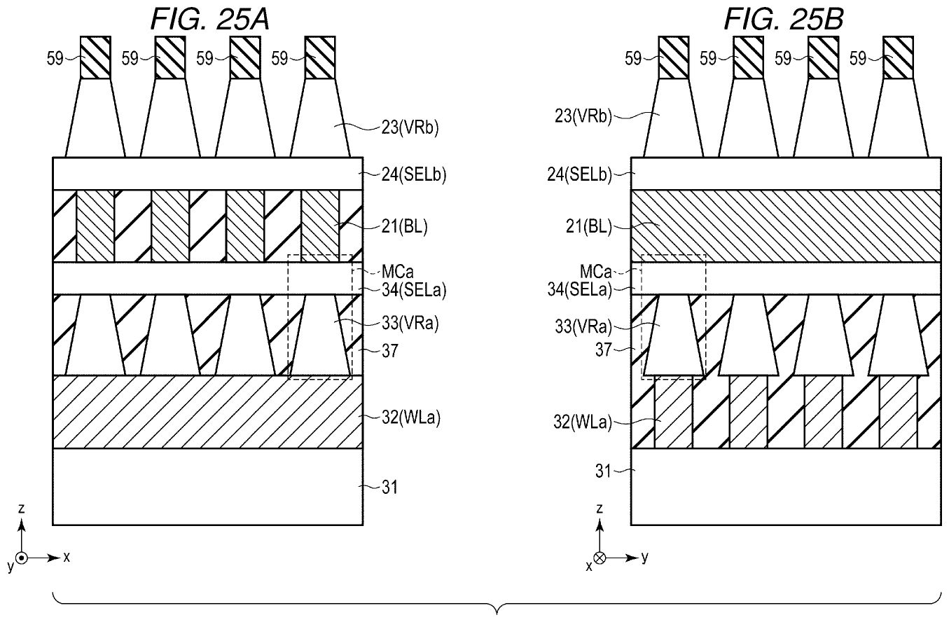

The memory cell array 11 of the fifth embodiment can be formed by the following steps. Similar to the fourth embodiment, the steps in FIGS. 9 to 11 of the first embodiment are performed first, and then, the step of FIGS. 22A and 22B of the fourth embodiment is performed. In the fifth embodiment, the step of FIGS. 22A and 22B continues to the step of FIGS. 25A and 25B. FIGS. 25A and 25B shows a step of the manufacturing process of a part of the storage device 1 according to the fifth embodiment. As shown in FIGS. 25A and 25B, the mask material 51 is removed and the region between the conductors 21 is filled by apart of the insulator 37. A layer for forming a switching element 24 is deposited on the upper surface of the conductor 21 and the insulator 37 therebetween and a stacked body for forming the resistance-variable element 23 is deposited on the upper surface of the layer of the switching element 24. Next, a mask material 59 is deposited on the upper surface of the stacked body. The mask material 59 remains above the region where the variable-resistance element 23 is to be formed, and is open at the other part thereof. The variable-resistance element 23 is formed by etching the stacked body by IBE using the mask material 59. The etching through the mask material 59 is stopped when the variable-resistance element 23 is patterned.

The mask material 59 is removed, the region between the variable-resistance elements 23 is filled by a part of the insulator 37, the conductor 22 is formed on the upper surface of the variable-resistance element 23, and the region between the conductors 22 is filled by a part of the insulator 37. As a result, the structure shown in FIGS. 24A and 24B is obtained.

According to the fifth embodiment, the switching elements 24 spread along the xy plane similar to the fourth embodiment and are connected to the bottom surfaces of each of the plurality of variable-resistance elements 23 arranged along the xy plane, and the switching elements 34 spread along the xy plane similar to the fourth embodiment and are connected to the upper surfaces of each of the plurality of variable-resistance elements 33 arranged along the xy plane. Accordingly, while the circuit in FIG. 3 is formed, the switching elements 24 and 34 can be easily formed and deterioration of the characteristics of the switching elements 24 and 34 can be prevented as described above.

### Sixth Embodiment

A sixth embodiment is different from the first embodiment in the structure of the memory cell array 11. More specifically, the sixth embodiment is different from the first embodiment in the position and shape of the switching element 34 and the shape of the switching element 24 along the z axis. Hereinafter, points different from those of the first embodiment will be mainly described.

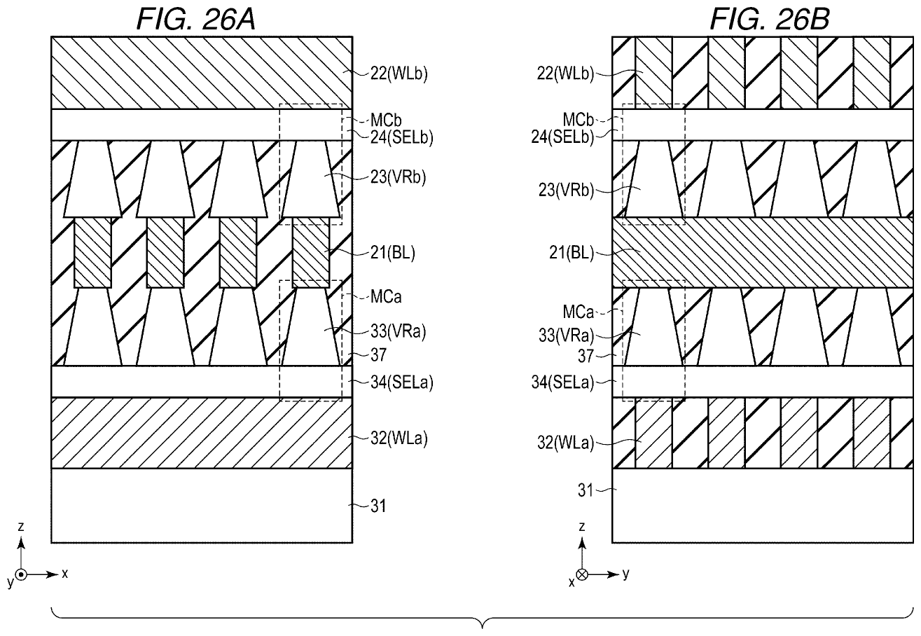

FIGS. 26A and 26B show cross-sectional structures of a part of the memory cell array 11 according to the sixth embodiment. FIG. 26A shows a structure taken along line VA-VA in FIGS. 3 and 4, and FIG. 26B shows a structure taken along line VB-VB in FIGS. 3 and 4.

As shown in FIGS. 26A and 26B, similar to FIGS. 19A and 19B of the third embodiment, in a direction of being separated from the board 31, a layer of the conductor 32, a layer of the switching element 34, a layer of the variable-resistance element 33, a layer of the conductor 21, a layer of the variable-resistance element 23, a layer of the switching element 24, and a layer of the conductor 22 are arranged in this order.

Similar to the fourth embodiment, the switching elements 34 spread along the xy plane and are connected to the bottom surfaces of each of the plurality of variable-resistance elements 33 arranged along the xy plane. Further, similar to the fourth embodiment, the switching elements 24 spread along the xy plane and are connected to the upper surfaces of each of the plurality of variable-resistance elements 23 arranged along the xy plane.

According to the structure of the memory cell array 11 of the third embodiment, both the memory cells MCa and MCb are the type B (refer to FIG. 2).

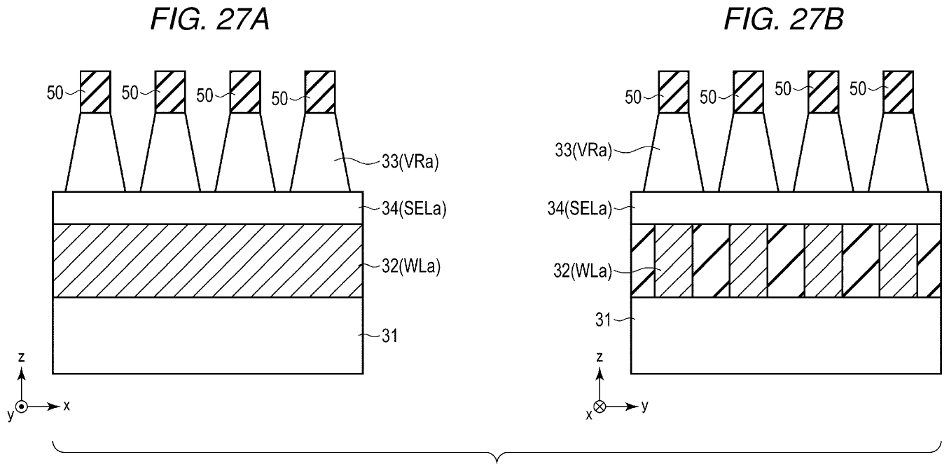

FIGS. 27A and 27B show a step of the manufacturing process of a part of the storage device 1 according to the sixth embodiment. As shown in FIGS. 27A and 27B, by the same steps as described with reference to FIGS. 9A and 9B, the conductor 32 is formed and the region between the conductors 32 is filled by a part of the insulator 37. A stacked body is formed on the upper surface of the conductor 32 and the insulator 37 therebetween, and the mask material 50 is deposited on the upper surface of the stacked body. The variable-resistance element 33 is formed by etching the stacked body by the ion beam etching (IBE) using the mask material 50. The etching through the mask material 50 is stopped when the variable-resistance element 33 is patterned.

The mask material 50 is removed and the region between the variable-resistance elements 33 is filled by a part of the insulator 37. Next, the conductor 21, the variable-resistance element 23, the switching element 24, and the conductor 22 are formed by steps similar to those described with reference to FIGS. 22 and 23 of the fourth embodiment. As a result, the structure shown in FIGS. 26A and 26B is obtained.

According to the sixth embodiment, the switching elements 24 spread along the xy plane similar to the fourth embodiment and are connected to the upper surfaces of each of the plurality of variable-resistance elements 23 arranged along the xy plane, and the switching elements 34 spread along the xy plane similar to the fourth embodiment and are connected to the bottom surfaces of each of the plurality of variable-resistance elements 33 arranged along the xy plane. Accordingly, while the circuit in FIG. 3 is formed, the switching elements 24 and 34 can be easily formed and deterioration of the characteristics of the switching elements 24 and 34 can be prevented as described above.

### Seventh Embodiment

A seventh embodiment is different from the first embodiment in the structure of the memory cell array 11. More specifically, in the seventh embodiment, in the arrangement on the xy plane of the variable-resistance elements 23 and 33, the shape of the conductor 22 and the conductor 32 and the arrangement on the xy plane, and the arrangement on the xy plane of the switching elements 24 and 34, are different from those of the first embodiment. Hereinafter, points different from those of the first embodiment will be mainly described.

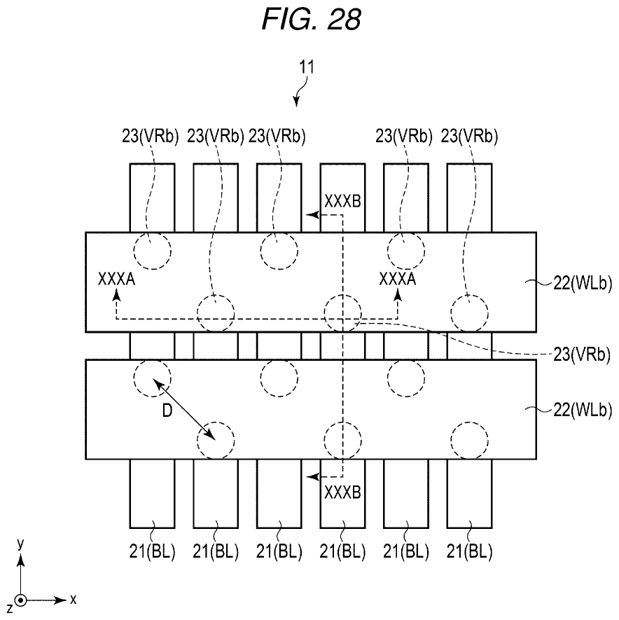

FIG. 28 shows a planar structure of a part of the memory cell array 11 according to the seventh embodiment. As shown in FIG. 28, the variable-resistance element 23 is arranged in a zigzag manner. In other words, the variable-resistance element 23 arranged along the x axis may configure one row, the two rows arranged along the y axis may include a first row and a second row, and the coordinates on the x axis of each of the variable-resistance elements 23 in the first row may be the coordinates on the x axis of any variable-resistance element 23 in the second row. Accordingly, in two rows arranged along the y axis, the variable-resistance element 23 is not arranged along the y axis. On the other hand, the three rows arranged along the y axis in order include the first row, the second row, and a third row, and the certain variable-resistance elements 23 in the first row are arranged with other variable-resistance elements 23 in the third row along the y axis.

The distance between each of the variable-resistance elements 23 and the variable-resistance element 23 closest to the row next to the row to which the variable-resistance element 23 belongs is, for example, D. Accordingly, the pitch of the variable-resistance elements 23 arranged along the y axis and the pitch of the variable-resistance elements 23 arranged along the x axis are both √2×D.

Each of the conductors 21 overlaps with the plurality of variable-resistance elements 23 arranged along the y axis on the xy plane, and extends along the plurality of variable-resistance elements 23 arranged along the y axis as will be described in detail later.

Each of the conductors 22 overlaps with two rows of the variable-resistance elements 23 arranged along the y axis on the xy plane and extends along the two rows of the variable-resistance element 23 arranged along the y axis.

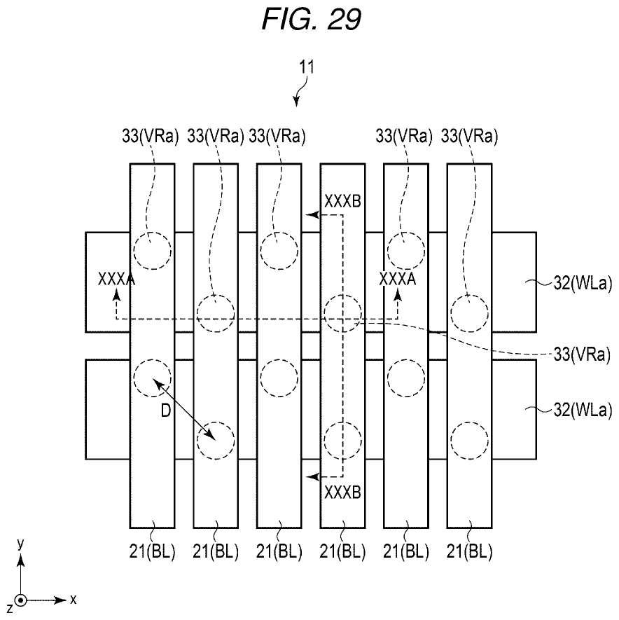

FIG. 29 shows a planar structure of another part of the memory cell array 11 of the seventh embodiment, and shows a lower structure along the z axis of the structure in FIG. 28. As shown in FIG. 29, the variable-resistance elements 33 are arranged in a zigzag manner. Each of the variable-resistance elements 33 has substantially the same shape as that of one variable-resistance element 23 and is disposed directly below the z axis of the corresponding variable-resistance element 23.

Each of the conductors 32 overlaps with the plurality of variable-resistance elements 23 arranged along the y axis on the xy plane, and extends along the plurality of variable-resistance elements 23 arranged along the y axis as will be described in detail later. Each of the conductors 32 has, for example, substantially the same planar shape as that of one conductor 22 and is disposed directly below the z axis of the corresponding conductor 22.

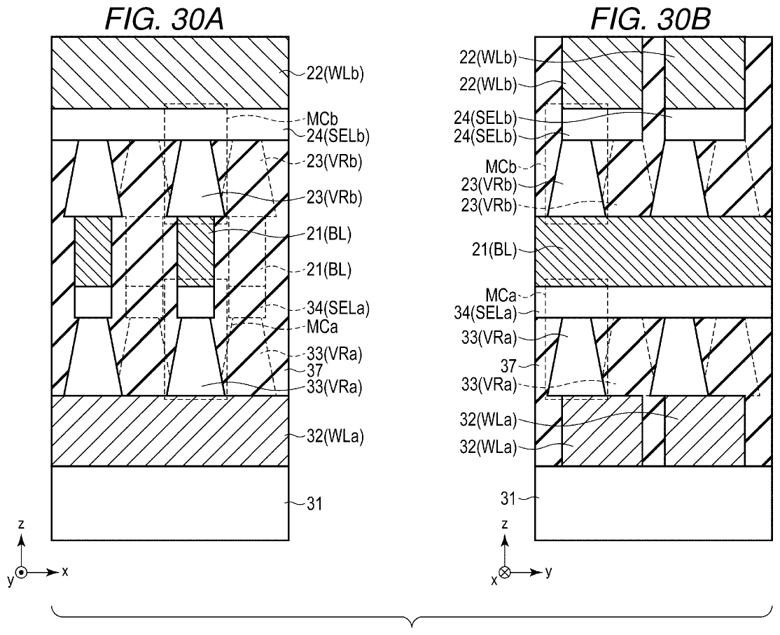

FIGS. 30A and 30B show cross-sectional structures of a part of the memory cell array 11 according to the seventh embodiment. FIG. 30A shows a structure taken along line XXXA-XXXA in FIG. 28, and FIG. 30B shows a structure taken along line XXXB-XXXB in FIG. 28.

As shown in FIGS. 30A and 30B, similar to FIGS. 5A and 5B of the first embodiment, in a direction of being separated from the board 31, a layer of the conductor 32, a layer of the variable-resistance element 33, a layer of the switching element 34, a layer of the conductor 21, a layer of the variable-resistance element 23, a layer of the switching element 24, and a layer of the conductor 22 are arranged in this order.

The two rows of the variable-resistance elements 33 arranged along the y axis are connected to the upper surface of each of the conductors 32. Each of the switching elements 34 is connected to the upper surfaces of each of the plurality of variable-resistance elements 33 in one row arranged along the y axis, is disposed below one conductor 21 on the z axis, and for example, has substantially the same planar shape as the planar shape of one corresponding conductor 21. Each of the conductors 21 is connected to the variable-resistance elements 23 in one row arranged along the y axis, on the upper surface. Each of the switching elements 24 is connected to the upper surfaces of each of the two rows of the variable-resistance elements 23 arranged along the y axis, is disposed below one conductor 22 on the z axis, and for example, has substantially the same planar shape as the planar shape of one corresponding conductor 22.

According to the structure of the memory cell array 11 of the seventh embodiment, the memory cell MCa is the type A (refer to FIG. 2) and the memory cell MCb is the type B.

The structure in FIGS. 30A and 30B can be formed by the same process as the manufacturing process of the first embodiment, and can be formed by changing the patterning of several materials in the manufacturing process of the first embodiment. Specifically, the patterning is changed such that the shapes and/or arrangement of the conductors 32, the variable-resistance elements 33, the switching elements 34, the conductors 21, the variable-resistance elements 23, the switching elements 24, and the conductors 22 are as shown in FIGS. 30A and 30B.

According to the seventh embodiment, similar to the first embodiment, the switching elements 34 extend along the y axis and are disposed between the layer on which the conductor 21 is disposed and the layer on which the variable-resistance element 33 is disposed, and the switching elements 24 extend along the x axis and are disposed between the layer on which the conductor 22 is disposed and the layer on which the variable-resistance element 23 is disposed. Accordingly, the same advantage as those in the first embodiment can be obtained.

Further, according to the seventh embodiment, the variable-resistance elements 23 and 33 are arranged in a zigzag manner on a plane. Therefore, in the seventh embodiment, it is possible to include more variable-resistance elements 23 and 33 than in the first embodiment per unit surface area, and it is possible to have a higher degree of integration degree than in the first embodiment. Furthermore, due to the arrangement in a zigzag manner, each of the conductors 22 can have a wider flat planar shape over the two rows of the variable-resistance elements 23 arranged along the y axis, and each of the conductors 32 can have a wider planar shape below the two rows of the variable-resistance elements 33 arranged along the y axis. Accordingly, the widths of the planes of the conductor 22 and the conductor 32 can be greater than the minimum pitch D of the variable-resistance elements 23 and 33. Therefore, the conductor 22 and the conductor 32 can be formed more easily than a case where the pitch of the variable-resistance elements 23 and 33 on the x axis and on the y axis is the minimum pitch D.

### Eighth Embodiment

An eighth embodiment is similar to the seventh embodiment and the second embodiment in the structure of the memory cell array 11 and relates to the combination of the seventh embodiment and the second embodiment. Hereinafter, points different from those of the seventh embodiment will be mainly described.

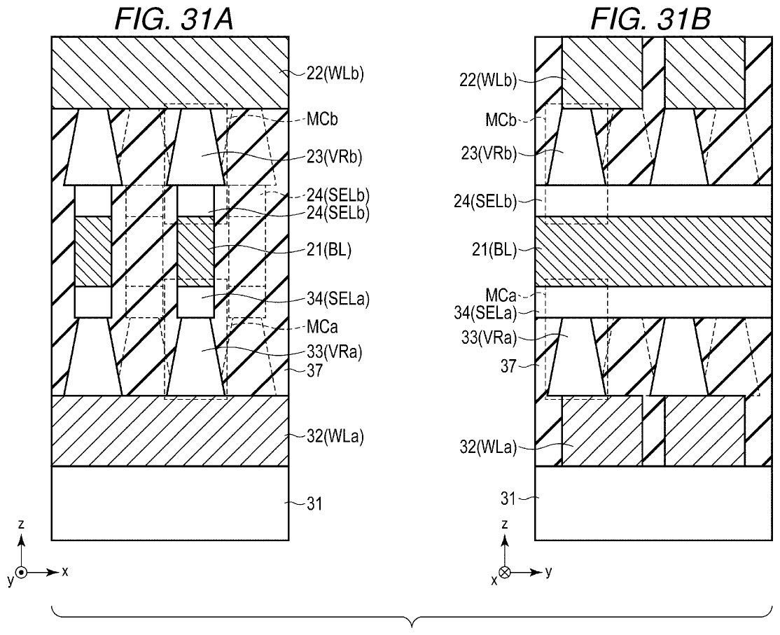

FIGS. 31A and 31B show cross-sectional structures of a part of the memory cell array 11 according to the eighth embodiment. FIG. 31A shows a structure taken along line XXXA-XXXA in FIGS. 28 and 29, and FIG. 31B shows a structure taken along line XXXB-XXXB in FIGS. 28 and 29.

As shown in FIGS. 31A and 31B, similar to FIGS. 17A and 17B of the second embodiment, in a direction of being separated from the board 31, a layer of the conductor 32, a layer of the variable-resistance element 33, a layer of the switching element 34, a layer of the conductor 21, a layer of the switching element 24, a layer of the variable-resistance element 23, and a layer of the conductor 22 are arranged in this order.

Each of the switching elements 24 is disposed on the upper surface of one conductor 21 and has, for example, substantially the same planar shape as the planar shape of one corresponding conductor 21, and is connected to the bottom surfaces of each of the variable-resistance elements 33 in one row arranged along the y axis.

According to the structure of the memory cell array 11 of the eighth embodiment, both the memory cells MCa and MCb are the type A (refer to FIG. 2).

The structure in FIGS. 31A and 31B can be formed by the same process as the manufacturing process of the second embodiment, and can be formed by changing the patterning of several materials in the manufacturing process of the second embodiment.

Specifically, the patterning is changed such that the shapes and (or) arrangement of the conductor 32, the variable-resistance element 33, the switching element 34, the conductor 21, the switching element 24, the variable-resistance element 23, and the conductor 22 are as shown in FIGS. 31A and 31B.

According to the eighth embodiment, similar to the second embodiment, the switching elements 24 extend along the y axis and are disposed between the layer on which the variable-resistance element 23 is disposed and the layer on which the conductor 21 is disposed, and the switching elements 34 extend along the y axis and are disposed between the layer on which the conductor 21 is disposed and the layer on which the variable-resistance element 33 is disposed. Accordingly, the same advantages as those in the second embodiment, that is, the same advantages as those in the first embodiment, can be obtained. Further, according to the eighth embodiment, similar to the seventh embodiment, the variable-resistance elements 23 and 33 are arranged in a zigzag manner on a plane. Therefore, the same advantage as those in the seventh embodiment can be obtained.

### Ninth Embodiment

A ninth embodiment is similar to the seventh embodiment and the third embodiment in the structure of the memory cell array 11 and relates to the combination of the seventh embodiment and the third embodiment. Hereinafter, points different from those of the seventh embodiment will be mainly described.

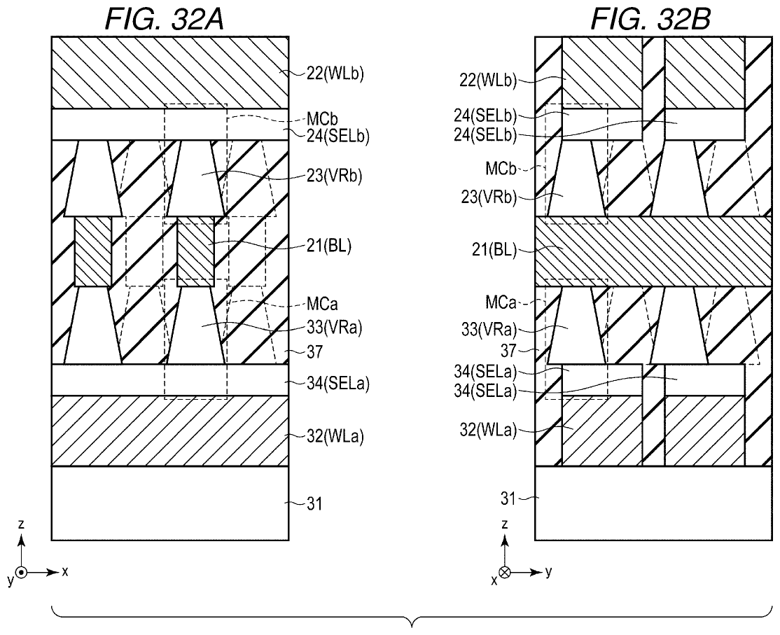

FIGS. 32A and 32B show cross-sectional structures of a part of the memory cell array 11 according to the ninth embodiment. FIG. 32A shows a structure taken along line XXXA-XXXA in FIGS. 28 and 29, and FIG. 32B shows a structure taken along line XXXB-XXXB in FIGS. 28 and 29.

As shown in FIGS. 32A and 32B, similar to FIGS. 19A and 19B of the third embodiment, in a direction of being separated from the board 31, a layer of the conductor 32, a layer of the switching element 34, a layer of the variable-resistance element 33, a layer of the conductor 21, a layer of the variable-resistance element 23, a layer of the switching element 24, and a layer of the conductor 22 are arranged in this order.

Each of the switching elements 34 is disposed on the upper surface of one conductor 32 and has, for example, substantially the same planar shape as the planar shape of one corresponding conductor 32, and is connected to the bottom surfaces of each of two rows of the variable-resistance elements 33 arranged along the y axis.

According to the structure of the memory cell array 11 of the ninth embodiment, both the memory cells MCa and MCb are the type B (refer to FIG. 2).

The structure in FIGS. 32A and 32B can be formed by the same process as the manufacturing process of the third embodiment, and can be formed by changing the patterning of several materials in the manufacturing process of the third embodiment. Specifically, the patterning is changed such that the shapes and (or) arrangement of the conductor 32, the switching element 34, the variable-resistance element 33, the conductor 21, the variable-resistance element 23, the switching element 24, and the conductor 22 are as shown in FIGS. 32A and 32B.

According to the ninth embodiment, similar to the third embodiment, the switching elements 24 extend along the x axis and are disposed between the layer on which the conductor 22 is disposed and the layer on which the variable-resistance element 23 is disposed, and the switching elements 34 extend along the x axis and are disposed between the layer on which the variable-resistance element 33 is disposed and the layer on which the conductor 32 is disposed. Accordingly, the same advantages as those in the third embodiment, that is, the same advantages as those in the first embodiment, can be obtained. Further, according to the ninth embodiment, similar to the seventh embodiment, the variable-resistance elements 23 and 33 are arranged in a zigzag manner on a plane. Therefore, the same advantage as those in the seventh embodiment can be obtained.

### Tenth Embodiment

A tenth embodiment is similar to the seventh embodiment in the structure of the memory cell array 11.

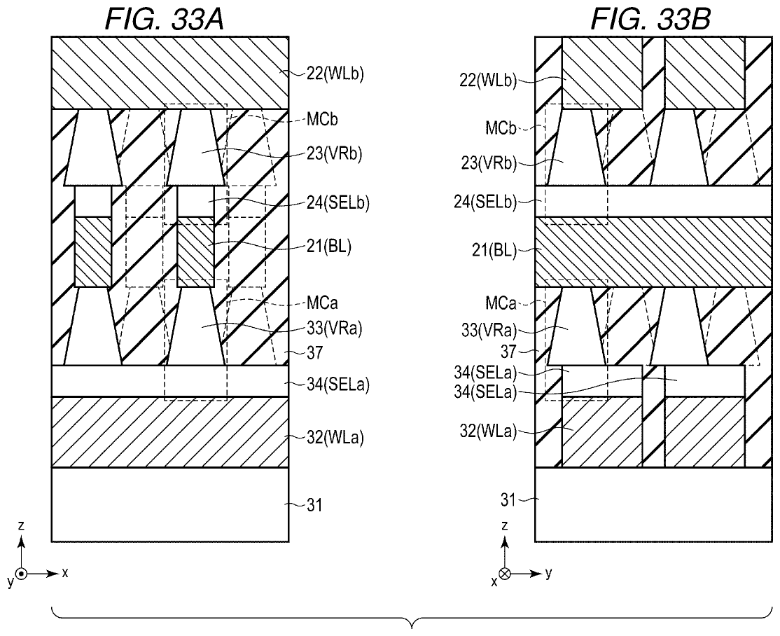

FIGS. 33A and 33B show cross-sectional structures of a part of the memory cell array 11 according to the tenth embodiment. FIG. 33A shows a structure taken along line XXXA-XXXA in FIGS. 28 and 29, and FIG. 33B shows a structure taken along line XXXB-XXXB in FIGS. 28 and 29.

As shown in FIGS. 33A and 33B, in a direction of being separated from the board 31, a layer of the conductor 32, a layer of the switching element 34, a layer of the variable-resistance element 33, a layer of the conductor 21, a layer of the switching element 24, a layer of the variable-resistance element 23, and a layer of the conductor 22 are arranged in this order.

Each of the switching elements 34 is disposed on the upper surface of one conductor 32 and has, for example, substantially the same planar shape as the planar shape of one corresponding conductor 32, and is connected to the bottom surfaces of each of two rows of the variable-resistance elements 33 arranged along the y axis.

Each of the switching elements 24 is disposed on the upper surface of one conductor 21 and has, for example, substantially the same planar shape as the planar shape of one corresponding conductor 21, and is connected to the bottom surfaces of each of the variable-resistance elements 33 in one row arranged along the y axis.

According to the structure of the memory cell array 11 of the tenth embodiment, the memory cell MCa is the type B (refer to FIG. 2) and the memory cell MCb is the type A.

The structure in FIGS. 33A and 33B can be formed by a process similar to a part of the manufacturing process of the third embodiment and a part of the manufacturing process of the second embodiment, and can be formed by changing the patterning of several materials at a part of the manufacturing process of the third embodiment and by changing the patterning of several materials at a part of the manufacturing process of the second embodiment. Specifically, the patterning is changed such that the shapes and (or) arrangement of the conductor 32, the switching element 34, the variable-resistance element 33, the conductor 21, the variable-resistance element 23, the switching element 24, and the conductor 22 are as shown in FIGS. 33A and 33B. More specifically, the process of patterning the layer 34A and the conductor 32A in the manufacturing process of the third embodiment is performed so as to obtain the switching element 34 and the conductor 32 of the structure and arrangement shown in FIGS. 33A and 33B. A process of patterning the stacked body 33A in the manufacturing process of the third embodiment is performed such that the variable-resistance element 33 of the arrangement shown in FIGS. 33A and 33B is obtained. A process of patterning the stacked body 23A in the manufacturing process of the second embodiment is performed such that the variable-resistance element 23 of the arrangement shown in FIGS. 33A and 33B is obtained. The process of patterning the layer 24A and the conductor 21A in the second embodiment is performed so as to obtain the switching element 24 and the conductor 21 of the structure shown in FIGS. 33A and 33B.

According to the tenth embodiment, similar to the second embodiment, the switching elements 24 extend along the y axis and are disposed between the layer on which the variable-resistance element 23 is disposed and the layer on which the conductor 21 is disposed, and similar to the third embodiment, the switching elements 34 extend along the x axis and are disposed between the layer on which the variable-resistance element 33 is disposed and the layer on which the conductor 32 is disposed. Accordingly, the same advantage as those in the first embodiment can be obtained. Further, according to the tenth embodiment, similar to the seventh embodiment, the variable-resistance elements 23 and 33 are arranged in a zigzag manner on a plane. Therefore, the same advantage as those in the seventh embodiment can be obtained.

### Eleventh Embodiment

An eleventh embodiment is different from the seventh embodiment in the structure of the memory cell array 11. More specifically, the eleventh embodiment is different from the seventh embodiment in the shape of the switching element 24 and the shape of the switching element 34. Hereinafter, points different from those of the seventh embodiment will be mainly described.

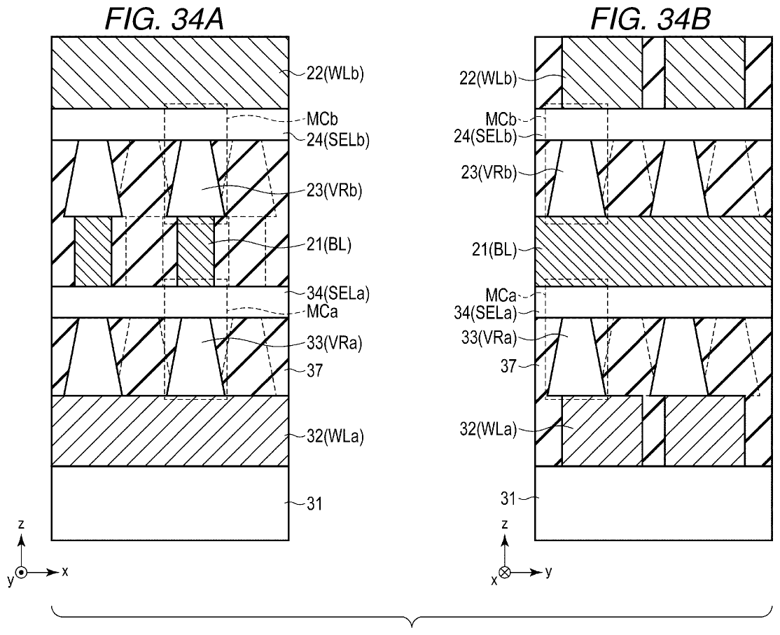

FIGS. 34A and 34B show cross-sectional structures of a part of the memory cell array 11 according to the eleventh embodiment. FIG. 34A shows a structure taken along line XXXA-XXXA in FIGS. 28 and 29, and FIG. 34B shows a structure taken along line XXXB-XXXB in FIGS. 28 and 29.

As shown in FIGS. 34A and 34B, similar to FIGS. 5A and 5B of the first embodiment, in a direction of being separated from the board 31, a layer of the conductor 32, a layer of the variable-resistance element 33, a layer of the switching element 34, a layer of the conductor 21, a layer of the variable-resistance element 23, a layer of the switching element 24, and a layer of the conductor 22 are arranged in this order.

Further, similar to the fourth embodiment, the switching elements 24 spread along the xy plane and are connected to the upper surfaces of each of the plurality of variable-resistance elements 23 arranged along the xy plane. Further, similar to the fourth embodiment, the switching elements 34 spread along the xy plane and are connected to the upper surfaces of each of the plurality of variable-resistance elements 33 arranged along the xy plane.

According to the structure of the memory cell array 11 of the eleventh embodiment, the memory cell MCa is the type A (refer to FIG. 2) and the memory cell MCb is the type B.

The structure in FIGS. 34A and 34B can be formed by the same process as the manufacturing process of the fourth embodiment, and can be formed by changing the patterning of several materials in the manufacturing process of the fourth embodiment.

Specifically, the patterning is changed such that the shapes and (or) arrangement of the conductor 32, the variable-resistance element 33, the conductor 21, the variable-resistance element 23, and the conductor 22 are as shown in FIGS. 34A and 34B.

According to the eleventh embodiment, similar to the fourth embodiment, the switching elements 24 and 34 spread along the xy plane. Therefore, the same advantage as those in the fourth embodiment can be obtained. Further, according to the eleventh embodiment, similar to the seventh embodiment, the variable-resistance elements 23 and 33 are arranged in a zigzag manner on a plane. Therefore, the same advantage as those in the seventh embodiment can be obtained.

### Twelfth Embodiment

A twelfth embodiment is different from the seventh embodiment in the structure of the memory cell array 11. More specifically, the twelfth embodiment is different from the seventh embodiment in the shape of the switching element 34 and the position and shape on the z axis of the switching element 24. Hereinafter, points different from those of the seventh embodiment will be mainly described.

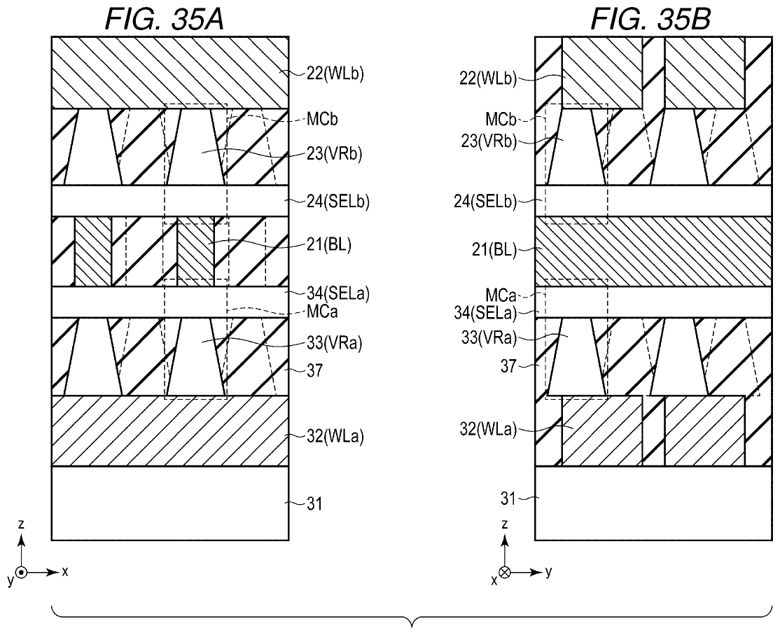

FIGS. 35A and 35B show cross-sectional structures of a part of the memory cell array 11 according to the twelfth embodiment. FIG. 35A shows a structure taken along line XXXA-XXXA in FIGS. 28 and 29, and FIG. 35B shows a structure taken along line XXXB-XXXB in FIGS. 28 and 29.

As shown in FIGS. 35A and 35B, similar to FIGS. 17A and 17B of the second embodiment, in a direction of being separated from the board 31, a layer of the conductor 32, a layer of the variable-resistance element 33, a layer of the switching element 34, a layer of the conductor 21, a layer of the switching element 24, a layer of the variable-resistance element 23, and a layer of the conductor 22 are arranged in this order.

Similar to the fourth embodiment, the switching elements 24 spread along the xy plane and are connected to the upper surfaces of each of the plurality of variable-resistance elements 23 arranged along the xy plane. Further, similar to the fourth embodiment, the switching elements 34 spread along the xy plane and are connected to the upper surfaces of each of the plurality of variable-resistance elements 33 arranged along the xy plane.

According to the structure of the memory cell array 11 of the twelfth embodiment, both the memory cells MCa and MCb are the type A (refer to FIG. 2).

The structure in FIGS. 35A and 35B can be formed by the same process as the manufacturing process of the fifth embodiment, and can be formed by changing the patterning of several materials in the manufacturing process of the fifth embodiment. Specifically, the patterning is changed such that the shapes and (or) arrangement of the conductor 32, the variable-resistance element 33, the conductor 21, the variable-resistance element 23, and the conductor 22 are as shown in FIGS. 35A and 35B.

According to the twelfth embodiment, similar to the fourth embodiment, the switching elements 24 and 34 spread along the xy plane. Therefore, the same advantage as those in the fourth embodiment can be obtained. Further, according to the twelfth embodiment, similar to the seventh embodiment, the variable-resistance elements 23 and 33 are arranged in a zigzag manner on a plane. Therefore, the same advantage as those in the seventh embodiment can be obtained.

### Thirteenth Embodiment

A thirteenth embodiment is different from the seventh embodiment in the structure of the memory cell array 11. More specifically, the thirteenth embodiment is different from the seventh embodiment in the position and shape on the z axis of the switching element 24 and the position and shape on the z axis of the switching element 34. Hereinafter, points different from those of the seventh embodiment will be mainly described.

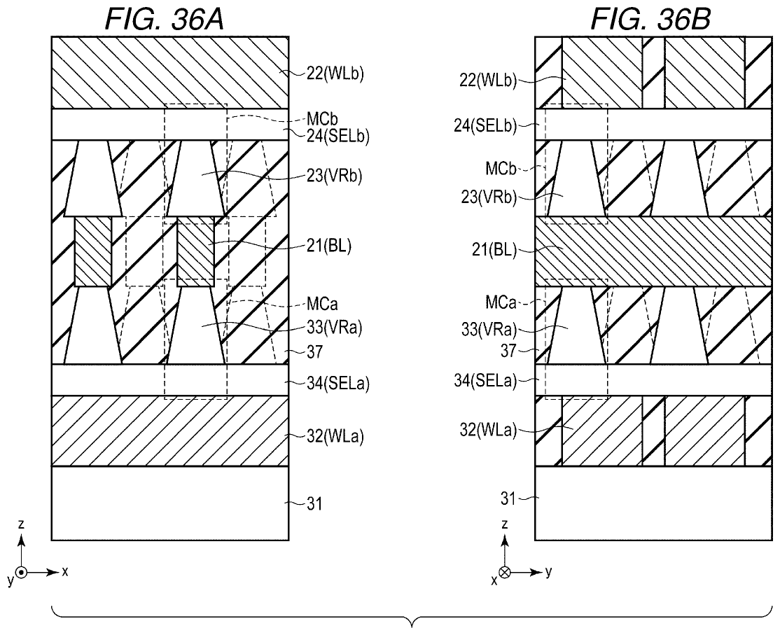

FIGS. 36A and 36B show cross-sectional structures of a part of the memory cell array 11 according to the thirteenth embodiment. FIG. 36A shows a structure taken along line XXXA-XXXA in FIGS. 28 and 29, and FIG. 36B shows a structure taken along line XXXB-XXXB in FIGS. 28 and 29.

As shown in FIGS. 36A and 36B, similar to FIGS. 19A and 19B of the third embodiment, in a direction of being separated from the board 31, a layer of the conductor 32, a layer of the switching element 34, a layer of the variable-resistance element 33, a layer of the conductor 21, a layer of the variable-resistance element 23, a layer of the switching element 24, and a layer of the conductor 22 are arranged in this order.

Similar to the fourth embodiment, the switching elements 24 spread along the xy plane and are connected to the upper surfaces of each of the plurality of variable-resistance elements 23 arranged along the xy plane. Further, similar to the fourth embodiment, the switching elements 34 spread along the xy plane and are connected to the bottom surfaces of each of the plurality of variable-resistance elements 33 arranged along the xy plane.

According to the structure of the memory cell array 11 of the thirteenth embodiment, both the memory cells MCa and MCb are the type B (refer to FIG. 2).

The structure in FIGS. 36A and 36B can be formed by the same process as the manufacturing process of the sixth embodiment, and can be formed by changing the patterning of several materials in the manufacturing process of the sixth embodiment. Specifically, the patterning is changed such that the shapes and (or) arrangement of the conductor 32, the variable-resistance element 33, the conductor 21, the variable-resistance element 23, and the conductor 22 are as shown in FIGS. 36A and 36B.

According to the thirteenth embodiment, similar to the fourth embodiment, the switching elements 24 and 34 spread along the xy plane. Therefore, the same advantage as those in the fourth embodiment can be obtained. Further, according to the thirteenth embodiment, similar to the seventh embodiment, the variable-resistance elements 23 and 33 are arranged in a zigzag manner on a plane. Therefore, the same advantage as those in the seventh embodiment can be obtained.

### Fourteenth Embodiment

A fourteenth embodiment is similar to the seventh embodiment in the structure of the memory cell array 11.

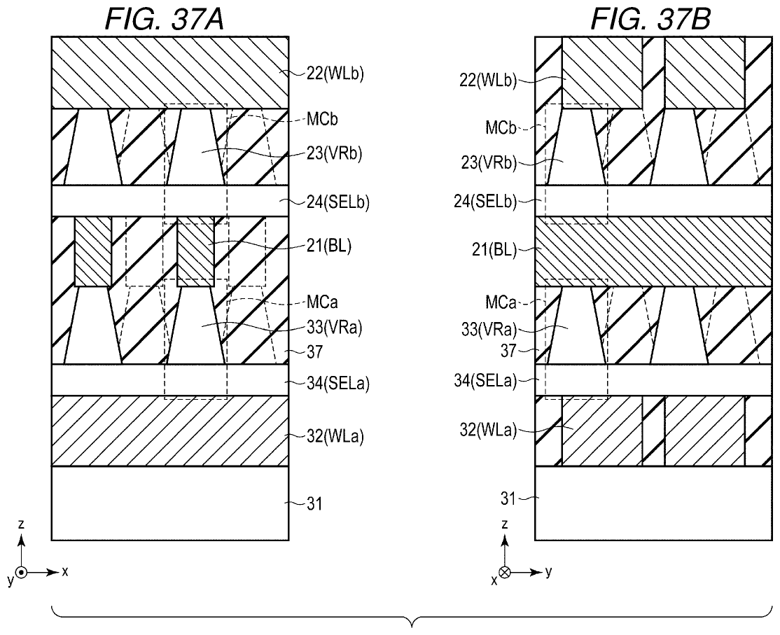

FIGS. 37A and 37B show cross-sectional structures of a part of the memory cell array 11 according to the fourteenth embodiment. FIG. 37A shows a structure taken along line XXXA-XXXA in FIGS. 28 and 29, and FIG. 37B shows a structure taken along line XXXB-XXXB in FIGS. 28 and 29.

As shown in FIGS. 37A and 37B, in a direction of being separated from the board 31, a layer of the conductor 32, a layer of the switching element 34, a layer of the variable-resistance element 33, a layer of the conductor 21, a layer of the switching element 24, a layer of the variable-resistance element 23, and a layer of the conductor 22 are arranged in this order.

Similar to the fourth embodiment, the switching elements 24 spread along the xy plane and are connected to the bottom surfaces of each of the plurality of variable-resistance elements 23 arranged along the xy plane. Further, similar to the fourth embodiment, the switching elements 34 spread along the xy plane and are connected to the bottom surfaces of each of the plurality of variable-resistance elements 33 arranged along the xy plane.

According to the structure of the memory cell array 11 of the fourteenth embodiment, the memory cell MCa is the type B (refer to FIG. 2) and the memory cell MCb is the type A.

The structure in FIGS. 37A and 37B can be formed by a process similar to a part of the manufacturing process of the third embodiment and a part of the manufacturing process of the second embodiment, and can be formed by changing the patterning of several materials at a part of the manufacturing process of the third embodiment and by changing the patterning of several materials at a part of the manufacturing process of the second embodiment. Otherwise, the formation can be performed by changing the patterning of several materials at a part of the manufacturing process of the tenth embodiment. Specifically, the patterning is changed such that the shapes and (or) arrangement of the conductor 32, the switching element 34, the variable-resistance element 33, the conductor 21, the variable-resistance element 23, the switching element 24, and the conductor 22 are as shown in FIGS. 37A and 37B.

According to the fourteenth embodiment, similar to the fourth embodiment, the switching elements 24 and 34 spread along the xy plane. Therefore, the same advantage as those in the fourth embodiment can be obtained. Further, according to the fourteenth embodiment, similar to the seventh embodiment, the variable-resistance elements 23 and 33 are arranged in a zigzag manner on a plane. Therefore, the same advantage as those in the seventh embodiment can be obtained.

### Modification Example

In the seventh to twelfth embodiments, the conductor 22 extends over the two rows of the variable-resistance elements 23 arranged along the y axis, the conductor 32 extends below the two rows of the variable-resistance elements 33 arranged along the y axis, and the conductor 21 extends along the one row of the variable-resistance elements 23 and 33 arranged along the y axis. Instead, the conductor 21 may extend below the two rows of the variable-resistance elements 23 arranged along the x axis and over the two rows of the variable-resistance elements 33 arranged along the x axis, the conductor 22 may extend over the one row of the variable-resistance elements 23 along the x axis, and the conductor 32 may extend below the one row of the variable-resistance elements 33 along the x axis.

The variable-resistance element VR may include phase-change elements, ferroelectric elements, or other elements. The phase-change element is used in a phase-change random access memory (PCRAM), contains chalcogenide and the like, and changes to a crystalline state or an amorphous state due to heat generated by the write current, and accordingly, a different resistor value is indicated. The variable-resistance element VR may include elements used for resistive RAM (ReRAM) including metal oxides or perovskite oxides. In a case of the variable-resistance element VR, the resistor value of the variable-resistance element VR changes by the application of different widths (pulse application period) of the write pulse, the different amplitudes (current value and voltage value), and different polarities (applying direction) of the write pulse.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A storage device, comprising:
a first conductor extending along a first direction;
a plurality of first variable-resistance elements on the first conductor;
a second conductor on the plurality of first variable-resistance elements, the second conductor extending along a second direction;
a plurality of second variable-resistance elements on the second conductor;
a third conductor on the plurality of second variable-resistance elements, the third conductor extending along the first direction;
a first switching element connected between the second conductor and a corresponding one of the first variable-resistance elements; and
a second switching element connected between the third conductor and a corresponding one of second variable-resistance elements.

2. The storage device according to claim 1, wherein the first switching element is between the second conductor and the corresponding one of the first variable-resistance elements.

3. The storage device according to claim 1, wherein the first switching element is between the first conductor and the corresponding one of the first variable-resistance elements.

4. The storage device according to claim 1, wherein the second switching element is between the second conductor and the corresponding one of the second variable-resistance elements.

5. The storage device according to claim 1, wherein the second switching element is between the third conductor and the corresponding one of the second variable-resistance elements.

6. The storage device according to claim 1, wherein
the plurality of first variable-resistance elements is arranged in a first plane parallel to the first direction and the second direction,
the plurality of second variable-resistance elements is arranged in a second plane parallel to the first direction and the second direction, the second plane spaced from the first plane in a third direction orthogonal to the first and second planes,
the first switching element is connected to first variable-resistance elements adjacent to each other along the second direction, and
the second switching element is connected to second variable-resistance elements adjacent to each other along the first direction.

7. The storage device according to claim 1, wherein
the first switching element is connected to an upper surface of at least two first variable-resistance elements adjacent to each other in the second direction,
a bottom surface of the second conductor is connected to the first switching element,
the second switching element is connected an upper surface of at least two second variable-resistance elements, and
a bottom surface of the third conductor is connected to the second switching element.

8. The storage device according to claim 1, wherein
the first switching element is connected an upper surface of at least two of first variable-resistance elements,
a bottom surface of the second conductor is connected to the first switching element,
an upper surface of the second conductor is connected to the second switching element, and
a bottom surface of at least two second variable-resistance elements is connected to the second switching element.

9. The storage device according to claim 1, wherein
the first switching element is connected to an upper surface of the first conductor and a bottom surface of at least two of first variable-resistance elements, and
the second switching element is connected to an upper surface of at least two second variable-resistance elements and a bottom surface of the third conductor.

10. The storage device according to claim 1, wherein
the plurality of first variable-resistance elements are arranged in a matrix pattern along the first direction and the second direction, and
the plurality of second variable-resistance elements are arranged in a matrix pattern along the first direction and the second direction.

11. The storage device according to claim 1, wherein
the plurality of first variable-resistance elements are in a zigzag pattern along at least one of the first and second directions, and
the plurality of second variable-resistance elements are in a zigzag pattern along at least one of the first and second directions.

12. The storage device according to claim 1, wherein the first switching element comprises a chalcogen.

13. A storage device, comprising:
a first conductor extending along a first direction;
a plurality of first variable-resistance elements arranged in a zigzag pattern above the first conductor;
a second conductor extending along a second direction above the plurality of first variable-resistance elements;
a plurality of second variable-resistance elements arranged in a zigzag pattern above the second conductor;
a third conductor extending along the first direction above the plurality of second variable-resistance elements;
a first switching element connected to at least two of the plurality of first variable-resistance elements; and
a second switching element connected to at least two of the plurality of second variable-resistance elements.

14. The storage device according to claim 13, wherein
the plurality of first variable-resistance elements includes a first row of the first variable-resistance elements arranged along the first direction and a second row of the first variable-resistance elements arranged along the first direction, and
coordinates along first axis for the first variable-resistance elements of the first row is offset from coordinates along the first direction for the first variable-resistance elements in the second row.

15. The storage device according to claim 13, wherein
the plurality of first variable-resistance elements are arranged in a first plane parallel to the first direction and the second direction,
the plurality of second variable-resistance elements are arranged in a second plane parallel to the first direction and the second direction, the second plane spaced from the first plane in a third direction orthogonal to the first and second planes,
the first switching element is connected to first variable-resistance elements adjacent to each other in the zigzag pattern along the second direction, and
the second switching element is connected to the second variable-resistance elements adjacent to each other in the zigzag pattern along the first direction.

16. The storage device according to claim 13, wherein
the first switching element is connected to an upper surface of at least two of first variable-resistance elements,
a bottom surface of the second conductor is connected to the first switching element,
the second switching element is connected to an upper surface of at least two second variable-resistance elements, and
a bottom surface of the third conductor is connected to the second switching element.

17. The storage device according to claim 13, wherein
the first switching element is connected an upper surface of at least two first variable-resistance elements,
a bottom surface of the second conductor is connected to the first switching element,
the second switching element is connected to an upper surface of the second conductor, and
the second switching element is connected to a bottom surface of at least two second variable-resistance elements.

18. The storage device according claim 13, wherein
the first switching element is connected to an upper surface of the first conductor,
the first switching element is connected to a bottom surface of at least two first variable-resistance elements,
the second switching element is connected to an upper surface of at least two second variable-resistance elements, and
the second switching element is connected to a bottom surface of the third conductor.

19. The storage device according to claim 13, wherein
the first switching element is connected to an upper surface of the first conductor,
the first switching element is connected to a bottom surface of at least two first variable-resistance elements,
the second switching element is connected to an upper surface of the second conductor, and
the second switching element is connected to a bottom surface of at least two second variable-resistance elements.

20. The storage device according to claim 13, wherein
the first switching element permits a current to flow when a voltage having a magnitude greater than or equal to a first value is applied across the first switching element, and
the second switching element permits a current to flow when a voltage having a magnitude greater than or equal to a second value is applied across the second switching element.
